(19) United States
(12) Patent Application Publication
(10) Pub. No.: US 2026/0032810 A1
(43) Pub. Date: Jan. 29, 2026

(54) FOLDABLE SUBSTRATES

(71) Applicant: CORNING INCORPORATED, CORNING, NY (US)

(72) Inventors: Huayun Deng, Painted Post, NY (US); Timothy James Kiczenski, Corning, NY (US); Yousef Kayed Qaroush, Horseheads, NY (US); ChuanChe Wang, Horseheads, NY (US); Xue Wang, Painted Post, NY (US); Yaochi Wei, Painted Post, NY (US); Ying Zhang, Ithaca, NY (US)

(21) Appl. No.: 19/143,739

(22) PCT Filed: Dec. 18, 2023
(86) PCT No.: PCT/US2023/084542

§ 371 Date: Jun. 26, 2025

Related U.S. Application Data
(60) Provisional application No. 63/436,965, filed on Jan. 4, 2023.
(60) Provisional application No. 63/607,208, filed on Dec. 7, 2023.

(51) Int. Cl. H05K 1/02; G06F 1/16; H05K 1/03

(52) U.S. Cl. CPC H05K 1/028; G06F 1/1652; H05K 1/0271; H05K 1/0306; H05K 2201/0191

(57) ABSTRACT

Foldable substrates comprise a first portion, a second portion, and a central portion positioned therebetween. The first portion comprises a substrate thickness and a first depth of compression. The central portion comprises a folding region positioned between a first transition region and a second transition region. A local thickness of the folding region between a first folding surface area and a second folding surface area, excluding any teeth, increases as a distance from a midline of the folding region decreases. In aspects, the folding region comprises a plurality of teeth extending from the first folding surface area. In aspects, the local thickness of the folding region as a function of the position along the folding width of the folding region can be proportional to a cube root of a sine of a fractional position, the fractional position scaled to range from 0 to pi radians across the folding width.

### CROSS-REFERENCE TO RELATED APPLICATIONS

This application claims the benefit of priority under 35 U.S.C. § 119 of U.S. Provisional Application Ser. No. 63/607,208 filed on Dec. 7, 2023 and U.S. Provisional Application Ser. No. 63/436,965 filed on Jan. 4, 2023, the contents of each of which are relied upon and incorporated herein by reference in their entireties.

### FIELD

The present disclosure relates generally to foldable substrates and, more particularly, to foldable substrates comprising portions with different thicknesses.

### BACKGROUND

Glass-based substrates are commonly used, for example, in display devices, for example, liquid crystal displays (LCDs), electrophoretic displays (EPD), organic light-emitting diode displays (OLEDs), plasma display panels (PDPs), or the like.

There is a desire to develop foldable versions of displays as well as foldable protective covers to mount on foldable displays. Foldable displays and covers should have good impact and puncture resistance. At the same time, foldable displays and covers should have small minimum bend radii (e.g., about 10 millimeters (mm) or less). However, plastic displays and covers with small minimum bend radii tend to have poor impact and/or puncture resistance. Furthermore, conventional wisdom suggests that ultra-thin glass-based sheets (e.g., about 75 micrometers (μm or microns) or less thick) with small minimum bend radii tend to have poor impact and/or puncture resistance. Furthermore, thicker glass-based sheets (e.g., greater than 125 micrometers) with good impact and/or puncture resistance tend to have relatively large minimum bend radii (e.g., about 30 millimeters or more). Consequently, there is a need to develop foldable apparatus that have low minimum bend radii and good impact and puncture resistance.

### SUMMARY

There are set forth herein foldable apparatus comprising foldable substrates, foldable substrates, and methods of making foldable apparatus and foldable substrates comprising foldable substrates that comprise a first portion, a second portion, and a central portion positioned therebetween. The substrate and/or the portions can comprise glass-based and/or ceramic-based portions, which can provide good dimensional stability, reduced incidence of mechanical instabilities, good impact resistance, and/or good puncture resistance. The portions can comprise glass-based and/or ceramic-based portions comprising one or more compressive stress regions, which can further provide increased impact resistance and/or increased puncture resistance. By providing a substrate comprising a glass-based and/or ceramic-based substrate, the substrate can also provide increased impact resistance and/or puncture resistance while simultaneously facilitating good folding performance. In aspects, the substrate thickness can be sufficiently large (e.g., from about 50 micrometers (microns or μm) to about 2 millimeters) to further enhance impact resistance and puncture resistance. Providing foldable substrates comprising a central portion comprising a central thickness that is less than a substrate thickness (e.g., first thickness of the first portion and/or second thickness of the second portion) (e.g., by about 10 μm or more) can enable a small parallel plate distance (e.g., about 10 millimeters (mm) or less, about 5 mm or less, or about 3 mm or less) based on the reduced thickness in the central portion, which can enable the foldability and/or rollability of the foldable substrate and/or foldable apparatus.

The inventors of the present application have determined that the local thickness profile of the folding region described herein can unexpectedly enable the foldable substrate to be folded into a substantially circular folded configuration (e.g., with a folded length of about 1.6 times the corresponding parallel plate distance). This is in contrast to the elliptical folded configuration (e.g., with a folded length of about 2.2 times the corresponding parallel plate distance) for a substrate with a uniform thickness in the region being folded. Additionally, the stress distribution in the folded configuration for a substrate with a uniform thickness is uneven, which can increase an incidence of damage and/or failure of the device relative to the stress distribution for folded foldable substrates with the thickness profile described herein. Unexpectedly, the increasing local thickness profile of the present disclosure enables the circular folded profile that decreases the length of the folded region and decreases stress concentrations along the bend. For example, in aspects, a smoothly varying surface can be provided in the folding region to facilitate folding into the substantially circular folded configuration. Alternatively, in aspects, a plurality of teeth (e.g., comprising substantially the substrate thickness) can increase a puncture resistance of the folding region while the folding region (excluding the teeth) can comprise the increasing local thickness profile discussed above that can facilitate folding into the substantially circular folded configuration.

In aspects, the foldable apparatus and/or foldable substrates can comprise one or more recesses, for example, a first central surface area recessed from a first major surface by a first distance and/or a second central surface area recessed from a second major surface by a second distance. Providing a first recess opposite a second recess can provide the central thickness that is less than a substrate thickness. Further, providing a first recess opposite a second recess can reduce a maximum bend-induced strain of the foldable apparatus, for example, between a central portion and a first portion and/or second portion since the central portion comprising the central thickness can be closer to a neutral axis of the foldable apparatus and/or foldable substrates than if only a single recess was provided. Additionally, providing the first distance substantially equal to the second distance can reduce the incidence of mechanical instabilities in the central portion, for example, because the foldable substrate is symmetric about a plane comprising a midpoint in the substrate thickness and the central thickness. Moreover, providing a first recess opposite a second recess can reduce a bend-induced strain of a material positioned in the first recess and/or second recess compared to a single recess with a surface recessed by the sum of the first distance and the second distance. Providing a reduced bend-induced strain of a material positioned in the first recess and/or the second recess can enable the use of a wider range of materials because of the reduced strain requirements for the material. For example, stiffer and/or more rigid materials can be positioned in the first recess, which can improve impact resistance, puncture resistance, abrasion resistance, and/or scratch resistance of the foldable apparatus. Additionally, controlling properties of a first material positioned in a first recess and a second material positioned in a second recess can control the position of a neutral axis of the foldable apparatus and/or foldable substrates, which can reduce (e.g., mitigate, eliminate) the incidence of mechanical instabilities, apparatus fatigue, and/or apparatus failure.

In aspects, the foldable apparatus and/or foldable substrates can comprise a first transition region attaching the central portion to the first portion and/or a second transition region attaching the central portion to the second portion. Providing transition regions with smoothly and/or monotonically decreasing (e.g., continuously decreasing) thicknesses can reduce stress concentration in the transition regions and/or avoid optical distortions. Providing a sufficient length of the transition region(s) (e.g., about 0.15 mm or more or about 0.3 mm or more) can avoid optical distortions that may otherwise exist from a sharp change in thickness of the foldable substrate.

Some example aspects of the disclosure are described below with the understanding that any of the features of the various aspects may be used alone or in combination with one another.
Aspect 1. A foldable substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a folding region positioned between a first transition region and a second transition region, the first transition region and the second transition region comprising a central thickness less than the substrate thickness, the folding region comprising a first folding surface area and a second folding surface area opposite the first folding surface area, a first folding compressive stress region extending to a first folding depth of compression from the first folding surface area, a second folding compressive stress region extending to a second folding depth of compression from the second folding surface area, a folding width of the folding region is defined between the first transition region and the second transition region, and a local thickness of the folding region between the first folding surface area and the second folding surface area in a direction of the substrate thickness increases as a distance from a midline of the folding region decreases,
wherein the foldable substrate comprises a glass-based material or a ceramic-based material.
Aspect 2. The foldable substrate of aspect 1, wherein the local thickness of the folding region varies between the central thickness and the substrate thickness with the local thickness at the midline of the folding region substantially equal to the substrate thickness.
Aspect 3. The foldable substrate of any one of aspects 1-2, wherein the local thickness of the folding region as a function of the position along the folding width of the folding region is proportional to a cube root of a sine of a fractional position, the fractional position scaled to range from 0 to pi radians across the folding width of the folding region.
Aspect 4. The foldable substrate of any one of aspects 1-3, wherein a thickness of the first transition region smoothly decreases from the substrate thickness to the central thickness as a distance from the first portion increases.
Aspect 5. The foldable substrate of any one of aspects 1-4, wherein the foldable substrate is symmetric about a plane equidistant from the first major surface and the second major surface.
Aspect 6. A foldable substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a folding region positioned between a first transition region and a second transition region, the first transition region and the second transition region comprising a central thickness less than the substrate thickness, the folding region comprising a plurality of teeth extending from a first folding surface area, the first folding surface area opposite a second folding surface, a folding width of the folding region is defined between the first transition region and the second transition region, and a local thickness of the folding region between the first folding surface area and a second folding surface area excluding the plurality of teeth increases as a distance from a midline of the folding region decreases,
wherein the foldable substrate comprises a glass-based material or a ceramic-based material.
Aspect 7. The foldable substrate of aspect 6, wherein a tooth thickness of a tooth of the plurality of teeth is substantially equal to the substrate thickness.
Aspect 8. The foldable substrate of aspect 6, wherein the midline of the folding region does not comprise a tooth of the plurality of teeth.
Aspect 9. The foldable substrate of any one of aspects 6-8, wherein a first width of a first tooth of the plurality of teeth is greater than a second width of a second tooth of the plurality of teeth, the first tooth is closer to the midline of the folding region than the second tooth is to the midline.
Aspect 10. The foldable substrate of any one of aspects 6-8, wherein a first width of a first tooth of the plurality of teeth is less than a second width of a second tooth of the plurality of teeth, the first tooth is closer to the midline of the folding region than the second tooth is to the midline.
Aspect 11. The foldable substrate of any one of aspects 6-10, wherein a first distance between a first adjacent pair of teeth of the plurality of teeth is less than a second distance between a second adjacent pair of teeth of the plurality of teeth, the first adjacent pair of teeth is closer to the midline of the folding region than the second adjacent pair of teeth is to the midline.
Aspect 12. The foldable substrate of any one of aspects 6-10, wherein a first distance between a first adjacent pair of teeth of the plurality of teeth is less than a second distance between a second adjacent pair of teeth of the plurality of teeth, the first adjacent pair of teeth is closer to the midline of the folding region than the second adjacent pair of teeth is to the midline.
Aspect 13. The foldable substrate of any one of aspects 6-12, wherein the local thickness of the folding region as a function of the position along the folding width of the folding region is proportional to a cube root of a sine of a fractional position, the fractional position scaled to range from 0 to pi radians across the folding width of the folding region.
Aspect 14. The foldable substrate of any one of aspects 6-13, wherein a thickness of the first transition region excluding the plurality of teeth smoothly decreases from the substrate thickness to the central thickness as a distance from the first portion increases.
Aspect 15. The foldable substrate of any one of aspects 1-14, wherein the folding region is symmetric about a plane extending through the midline of the folding region and equidistant from the first portion and the second portion.
Aspect 16. The foldable substrate of any one of aspects 1-15, wherein a folded configuration of the foldable substrate folded about the midline of the folding region in a Parallel Plate Test is substantially circular.
Aspect 17. The foldable substrate of any one of aspects 1-15, wherein the folding width of the folding region is substantially equal to a minimum parallel plate distance of the foldable substrate in a Parallel Plate Test.
Aspect 18. The foldable substrate of any one of aspects 1-17, wherein the foldable substrate achieves a parallel plate distance from 1 millimeter to 6 millimeters.
Aspect 19. The foldable substrate of any one of aspects 1-17, wherein the foldable substrate achieves a parallel plate distance of 3 millimeters.
Aspect 20. The foldable substrate of any one of aspects 1-19, wherein a first transition width of the first transition region is from about 100 micrometers to about 5 millimeters.
Aspect 21. The foldable substrate of any one of aspects 1-20, wherein the first compressive stress region comprises a first maximum compressive stress of about 400 MegaPascals or more, the second compressive stress region comprises a second maximum compressive stress, the third compressive stress region comprises a third maximum compressive stress of about 400 MegaPascals or more, and the fourth compressive stress region comprises a fourth maximum compressive stress.
Aspect 22. The foldable substrate of aspect 21, wherein the second maximum compressive stress is about 400 MegaPascals or more, and the fourth maximum compressive stress is about 400 MegaPascals or more.
Aspect 23. The foldable substrate of any one of aspects 1-22, wherein the substrate thickness is in a range from about 50 micrometers to about 2 millimeters.
Aspect 24. The foldable substrate of any one of aspects 1-22, wherein the substrate thickness is in a range from about 100 micrometers to about 200 micrometers.
Aspect 25. The foldable substrate of any one of aspects 1-24, wherein the central thickness in a range from about 25 micrometers to about 120 micrometers.
Aspect 26. The foldable substrate of any one of aspects 1-24, wherein the central thickness is in a range from about 25 micrometers to about 60 micrometers.
Aspect 27. The foldable substrate of any one of aspects 1-26, wherein the foldable substrate comprises a glass-based substrate.
Aspect 28. The foldable substrate of any one of aspects 1-26, wherein the foldable substrate comprises a ceramic-based substrate.
Aspect 29. A consumer electronic product, comprising:
a housing comprising a front surface, a back surface, and side surfaces;
electrical components at least partially within the housing, the electrical components comprising a controller, a memory, and a display, the display at or adjacent the front surface of the housing; and
a cover substrate disposed over the display,
wherein at least one of a portion of the housing or the cover substrate comprises the foldable substrate of any one of aspects 1-28.

### BRIEF DESCRIPTION OF THE DRAWINGS

The above and other features and advantages of aspects of the present disclosure are better understood when the following detailed description is read with reference to the accompanying drawings, in which:

FIG. 1 is a schematic view of an example foldable apparatus in a flat configuration according to aspects, wherein a schematic view of the folded configuration may appear as shown in FIG. 6;

FIG. 2 is a cross-sectional view of the foldable apparatus along line 2-2 of FIG. 1 comprising a foldable substrate according to aspects;

FIG. 3 is an alternative cross-sectional view of the foldable apparatus along line 2-2 of FIG. 1 comprising a foldable substrate according to aspects;

FIGS. 4A-4C and 5A-5C show alternative cross-sectional views of the foldable apparatus along line 2-2 of FIG. 1;

FIG. 6 is a schematic view of example foldable apparatus of aspects of the disclosure in a folded configuration wherein a schematic view of the flat configuration may appear as shown in FIG. 1;

FIG. 7 is a cross-sectional view of a testing apparatus to determine the minimum parallel plate distance of an example foldable substrate along line 7-7 of FIG. 6 that is a folded configuration of the foldable apparatus shown in FIG. 2 in a flat configuration;

FIG. 8 is a cross-sectional view of a testing apparatus to determine the minimum parallel plate distance of an example foldable substrate along line 7-7 of FIG. 6 that is a folded configuration of the foldable apparatus shown in FIG. 3 in a flat configuration;

FIG. 9 presents traces of the folded configuration for foldable the substrates shown in FIGS. 2-3, 4A-4C, and 5A-5C (e.g., Examples 1-6 and Comparative Example AA), where the horizontal axis (e.g., x-axis) and vertical axis (e.g., y-axis) correspond to physical distance in mm from a midpoint of the folded configuration;

FIG. 10 presents traces of the folded configuration for foldable substrates shown in FIGS. 2-3 and 7-8, where the horizontal axis (e.g., x-axis) and vertical axis (e.g., y-axis) correspond to physical distance in mm from a midpoint of the folded configuration for Examples 7-8; and

FIG. 11 presents stress in MegaPascals on the left-hand vertical axis (e.g., left side y-axis) as a function of an angular position (in radians and degrees on the horizontal axis (e.g., x-axis)) of foldable substrates in the folded configuration for Example 9 and Comparative Example BB while the right-hand vertical axis (e.g., right side y-axis) corresponds to local thickness in micrometers (μm);

FIG. 12 is a schematic plan view of an example consumer electronic device according to aspects;

FIG. 13 is a schematic perspective view of the example consumer electronic device of FIG. 12;

FIG. 14 is a schematic perspective view of a foldable consumer electronic product;

FIG. 15 presents stress in MegaPascals on the vertical axis (e.g., y-axis) as a function of an angular position (in radians and degrees on the horizontal axis (e.g., x-axis)) of foldable substrates in the folded configuration of Example 12 and Comparative Examples AA and CC while the right-hand vertical axis (e.g., right side y-axis) corresponds to local thickness in micrometers (μm);

FIG. 16 presents stress in MegaPascals on the vertical axis (e.g., y-axis) as a function of an angular position (in radians and degrees on the horizontal axis (e.g., x-axis)) of foldable substrates in the folded configuration of Example 11 and Comparative Example AA while the right-hand vertical axis (e.g., right side y-axis) corresponds to local thickness in micrometers (μm); and

FIG. 17 presents stress in MegaPascals on the vertical axis (e.g., y-axis) as a function of an angular position (in radians and degrees on the horizontal axis (e.g., x-axis)) of foldable substrates in the folded configuration of Example 13 and Comparative Examples AA and DD while the right-hand vertical axis (e.g., right side y-axis) corresponds to local thickness in micrometers (μm).

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Aspects will now be described more fully hereinafter with reference to the accompanying drawings in which example aspects are shown. Whenever possible, the same reference numerals are used throughout the drawings to refer to the same or like parts.

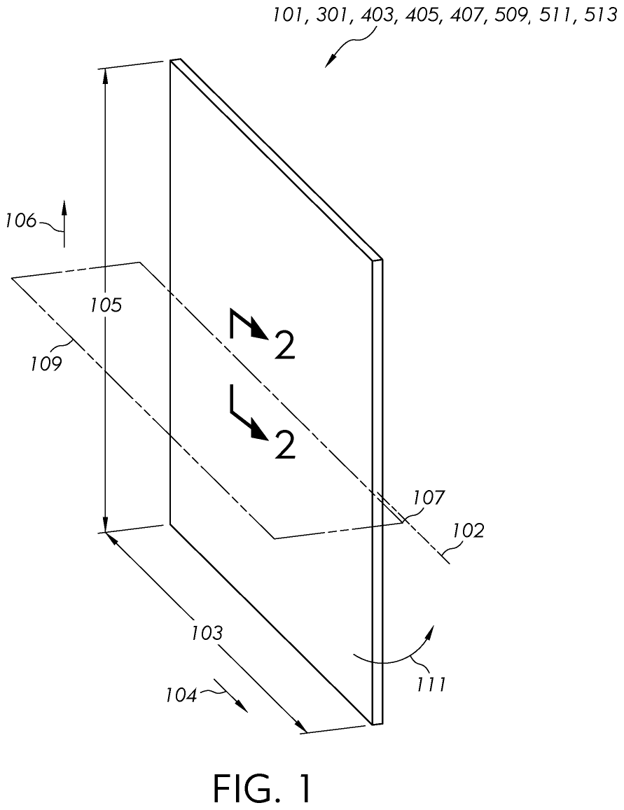

FIGS. 1-3, 4A-4C, 5A-5C and 7-8 illustrate views of foldable apparatus 101, 301, 403, 405, 407, 509, 511, 513, 601, and 801 comprising a foldable substrate 201 in accordance with aspects of the disclosure. Unless otherwise noted, a discussion of features of aspects of one foldable apparatus can apply equally to corresponding features of any aspect of the disclosure. For example, identical part numbers throughout the disclosure can indicate that, in some aspects, the identified features are identical to one another and that the discussion of the identified feature of one aspect, unless otherwise noted, can apply equally to the identified feature of any of the other aspects of the disclosure.

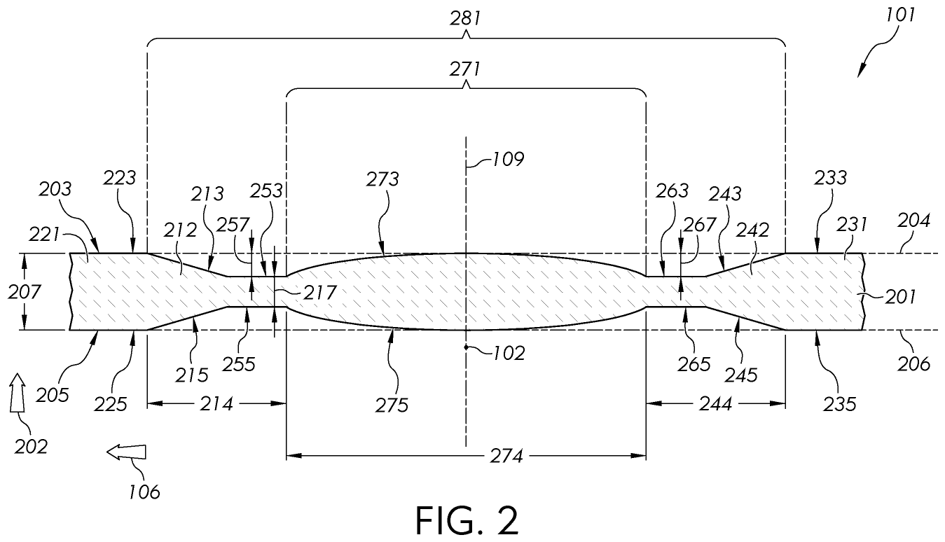

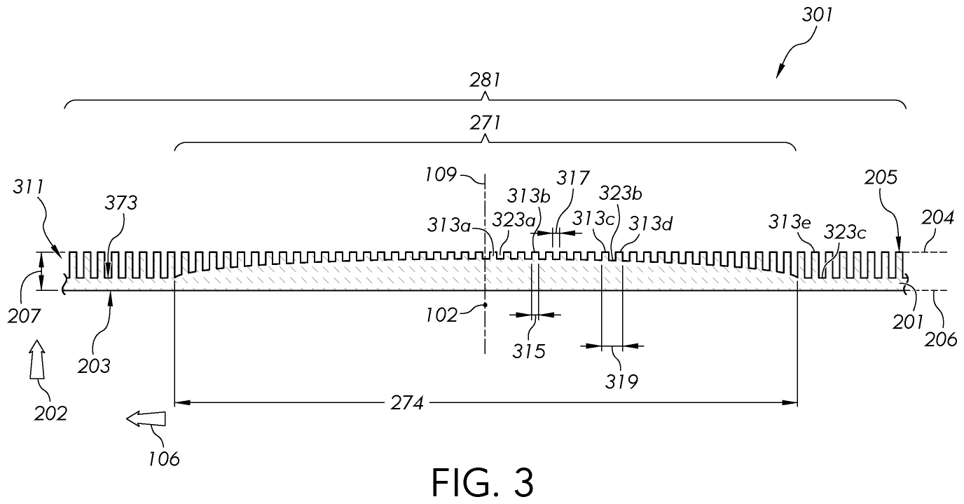

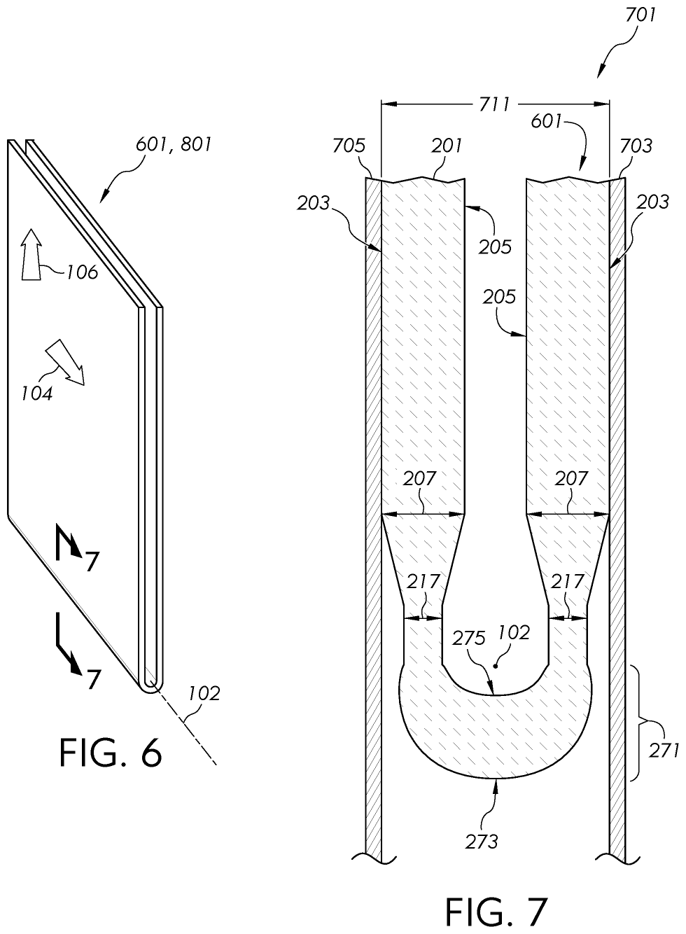

FIGS. 2-3, 4A-4C, and 5A-5C schematically illustrate example aspects of foldable apparatus 101, 301, 403, 405, 407, 509, 511, and 513 comprising the foldable substrate 201 in accordance with aspects of the disclosure in an unfolded (e.g., flat) configuration while FIGS. 6-8 illustrates an example aspect of a foldable apparatus 601 and 801 comprising the foldable substrate 201 in accordance with aspects of the disclosure in a folded configuration. The foldable apparatus 101 and the foldable substrate 201 comprise a first portion 221 and a second portion 231 with a central portion 281 and/or a folding region 271 positioned therebetween. Although not shown in FIGS. 3, 4A-4C, and 5A-5C, it is to be understood that the central portion 281 and/or the folding region 271 can be attached to a first portion 221 and/or second portion 231 similar to or identical to the corresponding portions shown in FIG. 2. Although not shown, it is to be understood that the foldable substrate can be combined with one or more polymer-based portions, adhesive layers, coatings, and/or display devices as the foldable apparatus.

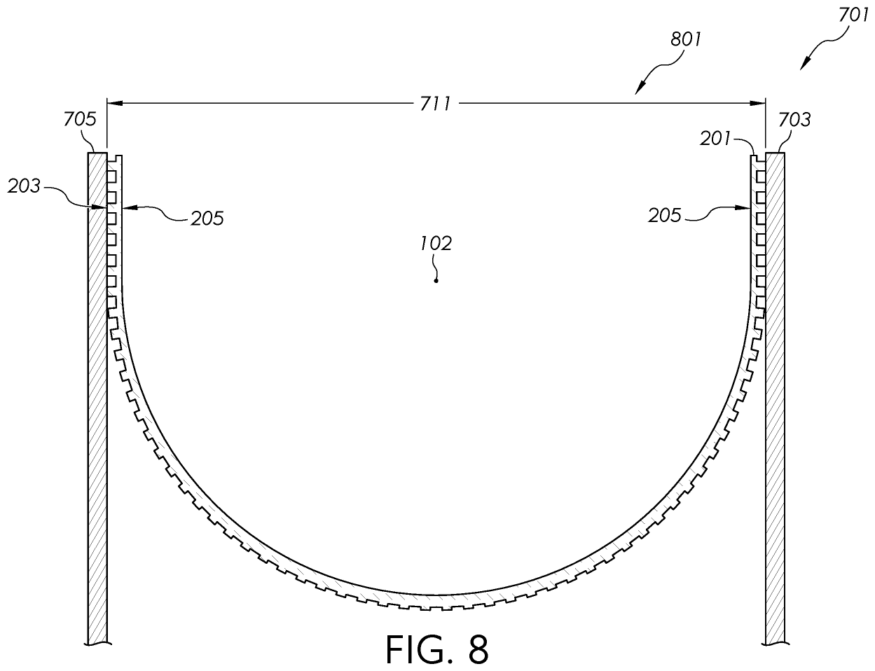

Throughout the disclosure, with reference to FIG. 1, the width 103 of the foldable apparatus 101, 301, 403, 405, 407, 509, 511, 513, 601, and/or 801 is considered the dimension of the foldable apparatus taken between opposed edges of the foldable apparatus in a direction 104 of a fold axis 102 of the foldable apparatus, wherein the direction 104 also comprises the direction of the width 103. Furthermore, throughout the disclosure, the length 105 of the foldable apparatus 101, 301, 403, 405, 407, 509, 511, 513, 601, and/or 801 is considered the dimension of the foldable apparatus 101, 301, 403, 405, 407, 509, 511, 513, 601, and/or 801 taken between opposed edges of the foldable apparatus 101, 301, 403, 405, 407, 509, 511, 513, 601, and/or 801 in a direction 106 perpendicular to the fold axis 102 of the foldable apparatus 101, 301, 403, 405, 407, 509, 511, 513, 601, and/or 801. It is to be understood that the direction 104 of the width 103 and/or the direction 106 of the length 105 can correspond to corresponding directions in the foldable substrate 201. In aspects, as shown in FIGS. 1-3, the foldable apparatus of any aspect of the disclosure can comprise a fold plane 109 that includes the fold axis 102 when the foldable apparatus is in the flat configuration (e.g., see FIGS. 2-3). In further aspects, as shown in FIGS. 2-3, the fold plane 109 can extend along the fold axis 102 and in a direction of a substrate thickness 207 when the foldable apparatus is in the flat configuration (e.g., see FIGS. 2-3). The fold plane 109 may comprise a central axis 107 of the foldable apparatus. In aspects, the foldable apparatus can be folded in a direction 111 (see FIG. 1) about the fold axis 102 extending in the direction 104 of the width 103 to form a folded configuration (e.g., see FIGS. 7-8 corresponding to folded configurations of the flat configurations shown in FIGS. 2-3, respectively). As shown, the foldable apparatus and/or the foldable substrate may include a single fold axis to allow the foldable apparatus and/or the foldable substrate to comprise a bifold wherein, for example, the foldable apparatus and/or the foldable substrate may be folded in half. In further aspects, the foldable apparatus and/or the foldable substrate may include two or more fold axes with each fold axis including a corresponding central portion similar or identical to the central portion 281 and/or folding region 271 discussed herein. For example, providing two fold axes can allow the foldable apparatus and/or the foldable substrate to comprise a trifold wherein, for example, the foldable apparatus and/or the foldable substrate may be folded with the first portion 221, the second portion 231, and a third portion similar or identical to the first portion or second portion with the central portion 281, folding region 271 and another central portion similar to or identical to the central portion and/or folding region positioned between the first portion and the second portion and between the second portion and the third portion, respectively.

The foldable substrate 201 can comprise a glass-based substrate and/or a ceramic-based substrate having a pencil hardness of 8H or more, for example, 9H or more. As used herein, pencil hardness is measured using ASTM D 3363-20 with standard lead graded pencils. Providing a glass-based foldable substrate and/or a ceramic-based foldable substrate can enhance puncture resistance and/or impact resistance.

In aspects, the foldable substrate 201 can comprise a glass-based substrate. As used herein, “glass-based” includes both glasses and glass-ceramics, wherein glass-ceramics have one or more crystalline phases and an amorphous, residual glass phase. A glass-based material (e.g., glass-based substrate) may comprise an amorphous material (e.g., glass) and optionally one or more crystalline materials (e.g., ceramic). Amorphous materials and glass-based materials may be strengthened. As used herein, the term “strengthened” may refer to a material that has been chemically strengthened, for example, through ion exchange of larger ions for smaller ions in the surface of the substrate, as discussed below. However, other strengthening methods, for example, thermal tempering, or utilizing a mismatch of the coefficient of thermal expansion between portions of the substrate to create compressive stress and central tension regions, may be utilized to form strengthened substrates. Exemplary glass-based materials, which may be free of lithia or not, comprise soda lime glass, alkali aluminosilicate glass, alkali-containing borosilicate glass, alkali-containing aluminoborosilicate glass, alkali-containing phosphosilicate glass, and alkali-containing aluminophosphosilicate glass. In aspects, glass-based material can comprise an alkali-containing glass or an alkali-free glass, either of which may be free of lithia or not. In aspects, the glass material can be alkali-free and/or comprise a low content of alkali metals (e.g., R₂O of about 10 mol % or less, wherein R₂O comprises Li₂O Na₂O, K₂O, or the more expansive list provided below). In one or more aspects, a glass-based material may comprise, in mole percent (mol %): SiO₂ in a range from about 40 mol % to about 80%, Al₂O₃ in a range from about 5 mol % to about 30 mol %, B₂O₃ in a range from 0 mol % to about 10 mol %, ZrO₂ in a range from 0 mol % to about 5 mol %, P₂O₅ in a range from 0 mol % to about 15 mol %, TiO₂ in a range from 0 mol % to about 2 mol %, R₂O in a range from 0 mol % to about 20 mol %, and RO in a range from 0 mol % to about 15 mol %. As used herein, R₂O can refer to an alkali-metal oxide, for example, Li₂O, Na₂O, K₂O, Rb₂O, and Cs₂O. As used herein, RO can refer to MgO, CaO, SrO, BaO, and ZnO. In aspects, a glass-based substrate may optionally further comprise in a range from 0 mol % to about 2 mol % of each of Na₂SO₄, NaCl, NaF, NaBr, K₂SO₄, KCl, KF, KBr, As₂O₃, Sb₂O₃, SnO₂, Fe₂O₃, MnO, MnO₂, MnO₃, Mn₂O₃, Mn₃O₄, Mn₂O₇. “Glass-ceramics” include materials produced through controlled crystallization of glass. In aspects, glass-ceramics have about 1% to about 99% crystallinity. Examples of suitable glass-ceramics may include Li₂O—Al₂O₃—SiO₂ system (i.e., LAS-System) glass-ceramics, MgO—Al₂O₃—SiO₂ system (i.e., MAS-System) glass-ceramics, ZnO×Al₂O₃×nSiO₂ (i.e., ZAS system), and/or glass-ceramics that include a predominant crystal phase including β-quartz solid solution, β-spodumene, cordierite, petalite, and/or lithium disilicate. The glass-ceramic substrates may be strengthened using the chemical strengthening processes. In one or more aspects, MAS-System glass-ceramic substrates may be strengthened in Li₂SO₄ molten salt, whereby an exchange of 2Li⁺ for Mg²⁺ can occur.

In aspects, the foldable substrate ₂O₁ can comprise a ceramic-based substrate. As used herein, “ceramic-based” includes both ceramics and glass-ceramics, wherein glass-ceramics have one or more crystalline phases and an amorphous, residual glass phase. Ceramic-based materials may be strengthened (e.g., chemically strengthened). In aspects, a ceramic-based material can be formed by heating a glass-based material to form ceramic (e.g., crystalline) portions. In further aspects, ceramic-based materials may comprise one or more nucleating agents that can facilitate the formation of crystalline phase(s). In aspects, ceramic-based materials can comprise one or more oxides, nitrides, oxynitrides, carbides, borides, and/or silicides. Example aspects of ceramic oxides include zirconia (ZrO₂), zircon (ZrSiO₄), an alkali-metal oxide (e.g., sodium oxide (Na₂O)), an alkali earth metal oxide (e.g., magnesium oxide (MgO)), titania (TiO₂), hafnium oxide (Hf₂O), yttrium oxide (Y₂O₃), iron oxides, beryllium oxides, vanadium oxide (VO₂), fused quartz, mullite (a mineral comprising a combination of aluminum oxide and silicon dioxide), and spinel (MgAl₂O₄). Example aspects of ceramic nitrides include silicon nitride (Si₃N₄), aluminum nitride (AlN), gallium nitride (GaN), beryllium nitride (Be₃N₂), boron nitride (BN), tungsten nitride (WN), vanadium nitride, alkali earth metal nitrides (e.g., magnesium nitride (Mg₃N₂)), nickel nitride, and tantalum nitride. Example aspects of oxynitride ceramics include silicon oxynitride, aluminum oxynitride, and a SiAlON (a combination of alumina and silicon nitride and can have a chemical formula, for example, Si₁₂₋ₘ₋ₙAlₘ₊ₙOₙN₁₆₋ₙ, Si₆₋ₙAlₙOₙN₈₋ₙ, or Si₂₋ₙAlₙO₁₊ₙN₂₋ₙ, where m, n, and the resulting subscripts are all non-negative integers). Example aspects of carbides and carbon-containing ceramics include silicon carbide (SiC), tungsten carbide (WC), an iron carbide, boron carbide (B₄C), alkali-metal carbides (e.g., lithium carbide (Li₄C₃)), alkali earth metal carbides (e.g., magnesium carbide (Mg₂C₃)), and graphite. Example aspects of borides include chromium boride (CrB₂), molybdenum boride (Mo₂B₅), tungsten boride (W₂B₅), iron boride, titanium boride, zirconium boride (ZrB₂), hafnium boride (HfB₂), vanadium boride (VB₂), Niobium boride (NbB₂), and lanthanum boride (LaB₆). Example aspects of silicides include molybdenum disilicide (MoSi₂), tungsten disilicide (WSi₂), titanium disilicide (TiSi₂), nickel silicide (NiSi), alkali earth silicide (e.g., sodium silicide (NaSi)), alkali-metal silicide (e.g., magnesium silicide (Mg₂Si)), hafnium disilicide (HfSi₂), and platinum silicide (PtSi).

Throughout the disclosure, an elastic modulus (e.g., Young's modulus) and/or a Poisson's ratio is measured using ISO 527-1:2019. Throughout the disclosure, the Young's modulus of the glass-based materials and ceramic-based materials are measured using the resonant ultrasonic spectroscopy technique set forth in ASTM E2001-13, titled “Standard Guide for Resonant Ultrasound Spectroscopy for Defect Detection in Both Metallic and Non-metallic Parts.” In aspects, the foldable substrate 201 can comprise an elastic modulus in a range from about 10 GPa to about 100 GPa, from about 40 GPa to about 100 GPa, from about 60 GPa to about 100 GPa, from about 60 GPa to about 80 GPa, from about 80 GPa to about 100 GPa, or any range or subrange therebetween.

Unless otherwise indicated, transmittance values are measured using a BYK Haze-Gard Dual (BYK Gardner). In aspects, the foldable substrate 201 can be optically transparent. As used herein, “optically transparent” or “optically clear” means an average transmittance of 70% or more in the wavelength range of 400 nm to 700 nm through a 1.0 mm thick piece of a material. In aspects, an “optically transparent material” or an “optically clear material” may have an average transmittance of 75% or more, 80% or more, 85% or more, or 90% or more, 92% or more, 94% or more, 96% or more in the wavelength range of 400 nm to 700 nm through a 1.0 mm thick piece of the material. The average transmittance in the wavelength range of 400 nm to 700 nm is calculated by measuring the transmittance of whole number wavelengths from about 400 nm to about 700 nm and averaging the measurements.

As shown in FIGS. 2-3, 4A-4C, and 5A-C, the foldable apparatus 101, 301, 403, 405, 407, 509, 511, and/or 513 comprise the foldable substrate 201 comprising a first major surface 203 and a second major surface 205 opposite the first major surface 203. As shown in FIGS. 2-3, 4A-4C, and 5A-5C, the first major surface 203 can extend along a first plane 204. The second major surface 205 can extend along a second plane 206. In aspects, as shown in FIG. 3, the second major surface 205 may be discontinuous, for example, being separated into a plurality of surfaces of a plurality of teeth 311 separated by a corresponding plurality of grooves. Although not shown in FIGS. 3, 4A-4C, and 5A-5C, the central portion 281 and/or the folding region 271 can be attached to a first portion 221 and/or second portion 231 similar to or identical to the corresponding portions shown in FIG. 2. In aspects, as shown, the second plane 206 can be parallel to the first plane 204. As used herein, a substrate thickness 207 can be defined between the first major surface 203 and the second major surface 205 as a distance between the first plane 204 and the second plane 206. In aspects, the substrate thickness 207 can be about 10 micrometers (μm) or more, about 25 μm or more, about 40 μm or more, about 50 μm or more, about 60 μm or more, about 70 μm or more, about 80 μm or more, about 90 μm or more, about 100 μm or more, about 125 μm or more, about 150 μm or more, about 200 μm or more, about 300 μm or more, about 2 millimeters (mm) or less, about 1 mm or less, about 800 μm or less, about 500 μm or less, about 300 μm or less, about 200 μm or less, about 180 μm or less, or about 160 μm or less. In aspects, the substrate thickness 207 can be in a range from about 10 μm to about 2 mm, from about 25 μm to about 2 mm, from about 40 μm to about 2 mm, from about 50 μm to about 2 mm, from about 60 μm to about 2 mm, from about 70 μm to about 2 mm, from about 70 μm to about 1 mm, from about 70 μm to about 800 μm, from about 80 μm to about 500 μm, from about 90 μm 500 μm, from about 100 μm to about 200 μm, from about 125 μm to about 200 μm, from about 150 μm to about 200 μm, from about 150 μm to about 160 μm, or any range or subrange therebetween.

As shown in FIG. 2, the first portion 221 of the foldable substrate 201 can comprise a first surface area 223 and a second surface area 225 opposite the first surface area 223. The first portion 221 will now be described with reference to the foldable apparatus 101 of FIG. 2 with the understanding that such description of the first portion 221, unless otherwise stated, can also apply to any aspect of the disclosure. In aspects, as shown, the first surface area 223 can comprise a planar surface, and/or the second surface area 225 of the first portion 221 can comprise a planar surface. In further aspects, as shown, the second surface area 225 can be parallel to the first surface area 223. In aspects, as shown, the first major surface 203 can comprise the first surface area 223 and the second major surface 205 can comprise the second surface area 225. In further aspects, the first surface area 223 can extend along the first plane 204. In further aspects, the second surface area 225 can extend along the second plane 206. In aspects, the substrate thickness 207 can correspond to the distance between the first surface area 223 of the first portion 221 and the second surface area 225 of the first portion 221. In aspects, the substrate thickness 207 can be substantially uniform across the first surface area 223. In aspects, a first thickness defined between the first surface area 223 and the second surface area 225 can be within one or more of the ranges discussed above with regards to the substrate thickness 207. In further aspects, the first thickness can comprise the substrate thickness 207. In further aspects, the first thickness of the first portion 221 may be substantially uniform between the first surface area 223 and the second surface area 225 across its corresponding length (i.e., in the direction 106 of the length 105 of the foldable apparatus) and/or its corresponding width (i.e., in the direction 104 of the width 103 of the foldable apparatus). As discussed above, it is to be understood that the foldable apparatus 301, 403, 405, 407, 509, 511, and/or 513 shown in FIGS. 3, 4A-4C, and 5A-5C can also comprise a first portion 221 similar to or identical to that described above in this paragraph attached to the central portion 281 and/or folding region 271.

As shown in FIG. 2, the second portion 231 of the foldable substrate 201 can comprise a third surface area 233 and a fourth surface area 235 opposite the third surface area 233. The second portion 231 will now be described with reference to the foldable apparatus 101 of FIG. 2 with the understanding that such description of the second portion 231, unless otherwise stated, can also apply to any aspect of the disclosure. In aspects, as shown, the third surface area 233 of the second portion 231 can comprise a planar surface, and/or the fourth surface area 235 of the second portion 231 can comprise a planar surface. In further aspects, the third surface area 233 of the second portion 231 can be in a common plane with the first surface area 223 of the first portion 221. In further aspects, as shown, the fourth surface area 235 can be parallel to the third surface area 233. In further aspects, the fourth surface area 235 of the second portion 231 can be in a common plane with the second surface area 225 of the first portion 221. A second thickness can be defined between the third surface area 233 of the second portion 231 and the fourth surface area 235 of the second portion 231. In aspects, the second thickness can be within the range discussed above with regards to the substrate thickness 207. In further aspects, the second thickness can comprise the substrate thickness 207. In further aspects, as shown, the second thickness can be substantially equal to the substrate thickness 207 (e.g., first thickness). In aspects, the second thickness of the second portion 231 may be substantially uniform between the third surface area 233 and the fourth surface area 235. As discussed above, it is to be understood that the foldable apparatus 301, 403, 405, 407, 509, 511, and/or 513 shown in FIGS. 3, 4A-4C, and 5A-5C can also comprise a second portion 231 similar to or identical to that described above in this paragraph attached to the central portion 281 and/or folding region 271.

As shown in FIG. 2, the foldable substrate 201 can comprise a central portion 281 positioned between the first portion 221 and the second portion 231. In aspects, as shown in FIGS. 2-3, the central portion 281 can comprise a folding region 271 therein comprising a first folding surface area 273 or 373 and/or a second folding surface area 275 opposite the first folding surface area 273 or 373. In aspects, as shown in FIG. 2, the central portion can further comprise a first transition region 212, a second transition region 242, and/or one or more recessed surface areas 253, 255, 263, and/or 265 attaching the folding region 271 to the first portion 221 and/or the second portion 231.

In aspects, as shown in FIG. 2, the central portion 281 can comprise a central thickness 217 defined a minimum thickness of the foldable substrate 201 in a direction 202 of the substrate thickness 207 for the central portion 281 of the foldable substrate 201. Consequently, the central thickness 217 is less than the substrate thickness 207. For example, as shown in FIG. 2, the central thickness 217 occurs between a first recessed surface area 253 and a second recessed surface area 255. Additionally, the central thickness 217 can occur at other locations that can be symmetric about the fold plane 109, for example, as between a third recessed surface area 263 and a fourth recessed surface area 265 that can be symmetric to the first recessed surface area 253 and the second recessed surface area 255 when reflected across the fold plane 109.

In aspects, the central thickness 217 can be about 1 μm or more, about 5 μm or more, about 10 μm or more, about 25 μm or more, about 40 μm or more, about 120 μm or less, about 100 μm or less, about 80 μm or less, about 60 μm or less, or about 50 μm or less. In aspects, the central thickness 217 can be in a range from about 1 μm to about 120 μm, from about 5 μm to about 120 μm, from about 10 μm to about 120 μm, from about 10 μm to about 120 μm, from about 25 μm to about 120 μm, from about 25 μm to about 100 μm, from about 25 μm to about 80 μm, from about 25 μm to about 60 μm, from about 40 μm to about 60 μm, or any range or subrange therebetween. In aspects, the central thickness 217 can be less than the substrate thickness 207 by about 10 μm or more, about 20 μm or more, about 30 μm or more, about 40 μm or more, about 50 μm or more, or about 60 μm or more. In aspects, the central thickness 217 as a percentage of the substrate thickness 207 can be about 0.5% or more, about 1% or more, about 2% or more, about 5% or more, about 6% or more, about 40% or less, about 30% or less, about 20% or less, about 13% or less, about 10% or less, or about 8% or less. In aspects, the central thickness 217 as a percentage of the substrate thickness 207 can be in a range from about 0.5% to about 40%, from about 0.5% to about 30%, from about 0.5% to about 20%, from about 0.5% to about 13%, from about 1% to about 13%, from about 1% to about 10%, from about 2% to about 10%, from about 2% to about 8%, from about 5% to about 8%, from about 6% to about 8%, or any range or subrange therebetween.

In aspects, as shown in FIG. 2, the first transition region 212 can comprise a first transition surface area 213 extending from the first surface area 223 and/or a second transition surface area 215 extending from the second surface area 225. In aspects, as shown in FIG. 2, a thickness of the first transition region 212 can decrease between the substrate thickness 207 of the first portion 221 and the central thickness 217. In aspects, as shown in FIG. 2, the second transition region 242 can comprise a third transition surface area 243 extending from the third surface area 233 and/or a fourth transition surface area 245 extending from the fourth surface area 235. In further aspects, as shown, a thickness of the first transition region 212 and/or the second transition region 242 can smoothly decrease, monotonically decrease, and/or smoothly and monotonically decrease between the substrate thickness 207 of the first portion 221 and the central thickness 217. As used herein, a thickness decreases smoothly if changes in the cross-sectional area are smooth (e.g., gradual) rather than abrupt (e.g., step) changes in thickness. As used herein, a thickness decreases monotonically in a direction if the thickness decreases for a portion and for the rest of the time either stays the same, decreases, or a combination thereof (i.e., the thickness decreases but never increases in the direction). Providing a smooth shape of the first transition region and/or the second transition region can reduce optical distortions. Providing a monotonically decreasing thickness of the first transition region and/or the second transition region can reduce an incidence of mechanical instabilities and/or decrease a visibility of the transition region.

In aspects, as shown in FIG. 2, the first transition surface area 213 can comprise a linearly inclined surface extending from the first surface area 223. In aspects, although not shown, the first transition surface area can comprise a concave up shape, for example, with a local slope of the first transition surface area smoothly transitioning to a first recessed surface area 253 while a local slope of the first transition surface area is substantially different from a slope of the first surface area 223. In aspects, although not shown, the first transition surface area can comprise a sigmoid shape. In aspects, although not shown, a local slope of the first transition surface area can be greater at a midpoint of the first transition surface area than where the first transition surface area meets the first recessed surface area 253 and where the first transition surface area meets the first surface area 223. In aspects, although not shown, the first transition surface area can comprise a convex up shape, for example, with a local slope of the first transition surface area smoothly transitioning to a slope of the first surface area 223 while a local slope of the first transition surface area is substantially different from a slope of the first recessed surface area 253. In aspects, the second transition surface area can comprise one of the shapes or properties discussed above in this paragraph for the first transition surface area. For example, as shown in FIG. 2, the second transition surface area 215 can comprise a linearly inclined surface extending between the second surface area 225 (e.g., from the second surface area 225 to a second recessed surface area 255).

In aspects, as shown in FIG. 2, the third transition surface area 243 can comprise a linearly inclined surface extending from the third surface area 233. In aspects, although not shown, the third transition surface area can comprise a concave up shape, for example, with a local slope of the first transition surface area smoothly transitioning to a third recessed surface area 263 while a local slope of the third transition surface area is substantially different from a slope of the third surface area 233. In aspects, although not shown, the third transition surface area can comprise a sigmoid shape. In aspects, although not shown, a local slope of the third transition surface area can be greater at a midpoint of the third transition surface area than where the third transition surface area meets the third recessed surface area 263 and where the second transition surface area meets the third surface area 233. In aspects, although not shown, the third transition surface area can comprise a convex up shape, for example, with a local slope of the third transition surface area smoothly transitioning to a slope of the third surface area 233 while a local slope of the third transition surface area is substantially different from a slope of the third recessed surface area 263. In aspects, the fourth transition surface area can comprise one of the shapes or properties discussed above in this paragraph for the third transition surface area. For example, as shown in FIG. 2, the fourth transition surface area 245 can comprise a linearly inclined surface extending between from the fourth surface area 235 (e.g., from the fourth surface area 235 to a fourth recessed surface area 265).

In aspects, as shown in FIG. 2, the first recessed surface area 253 can be recessed from the first major surface 203 by a first distance 257. In further aspects, the first distance 257 can be about 30 μm or more, about 40 μm or more, about 50 μm or more, about 70 μm or more, about 100 μm or more, about 1 mm or less, about 800 μm or less, about 500 μm or less, about 300 μm or less, about 100 μm or less, or about 60 μm or less. In further aspects, the first distance 257 can be in a range from about 30 μm to about 1 mm, from about 30 μm to about 800 μm, from about 30 μm to about 500 μm, from about 40 μm to about 300 μm, from about 50 μm to about 100 μm, from about 50 μm to about 60 μm, or any range or subrange therebetween. In aspects, as shown, the second recessed surface area 255 can be recessed from the second major surface 205. In further aspects, the second recessed surface area 255 can be recessed from the second major surface 205 by a distance within one or more of the ranges discussed above in this paragraph and/or equal to the first distance. In aspects, as shown, the first recessed surface area 253 and/or the second recessed surface area 255 can be planar and/or parallel to the first plane 204 and/or the second plane 206 that the first major surface 203 and/or the second major surface 205 extend along, respectively.

In aspects, as shown in FIG. 2, the third recessed surface area 263 can be recessed from the first major surface 203 by a second distance 267. In further aspects, the second distance 267 can be within one or more of the ranges discussed above for the first distance 257. In further aspects, the second distance 267 can be substantially equal to the first distance 257. In aspects, as shown, the fourth recessed surface area 265 can be recessed from the second major surface 205. In further aspects, fourth recessed surface area 265 can be recessed from the second major surface 205 by a distance within one or more of the ranges discussed above for the first distance 257 and/or the second distance 267. In aspects, as shown, the third recessed surface area 263 and/or the fourth recessed surface area 265 can be planar and/or parallel to the first plane 204 and/or the second plane 206 that the first major surface 203 and/or the second major surface 205 extend along, respectively.

In aspects, a first transition width 214 of the first transition region 212 is defined between the first portion 221 comprising the substrate thickness 207 and the folding region 271, where a local thickness starts to increase (e.g., from the central thickness 217). In further aspects, the first transition width 214 can be about 100 μm or more, about 200 μm or more, about 300 μm or more, about 500 μm or more, about 700 μm or more, about 1 mm or more, about 5 mm or less, about 4 mm or less, about 3 mm or less, about 1 mm or less, about 800 μm or less, or about 600 μm or less. In further aspects, the first transition width 214 can be in a range from about 100 μm to about 5 mm, from about 100 μm to about 4 mm, from about 200 μm to about 3 mm, from about 300 μm to about 1 mm, from about 500 μm to about 1 mm, from about 500 μm to about 800 μm, from about 500 μm to about 600 μm, or any range or subrange therebetween. In aspects, a second transition width 244 of the second transition region 242 is defined between the second portion 231 comprising the substrate thickness 207 and the folding region 271, where a local thickness starts to increase (e.g., from the central thickness 217). In further aspects, the second transition width 244 can be within one or more of the ranges discussed above in this paragraph for the first transition width 214 and/or substantially equal to the first transition width 214.

Providing a first recess (e.g., between the first recessed surface area 253 and/or third recessed surface area 263 and the first plane 204) opposite a second recess (e.g., between the second recessed surface area 255 and/or fourth recessed surface area 265 and the second plane 206) can reduce a bend-induced strain of any material positioned in the first recess and/or second recess compared to a single recess with a surface recessed by the sum of the first distance and the second distance. Providing a reduced bend-induced strain of a material positioned in the first recess and/or the second recess can enable the use of a wider range of materials because of the reduced strain requirements for the material. For example, stiffer and/or more rigid materials (can be positioned in the first recess, which can improve impact resistance, puncture resistance, abrasion resistance, and/or scratch resistance of the foldable apparatus.

In aspects, as shown in FIG. 2, the folding region 271 can be positioned between the first transition region 212 and the second transition region 242. In aspects, as shown, the folding region 271 comprises a first folding surface area 273 and a second folding surface area 275 opposite the first folding surface area 273. In further aspects, as shown, a local thickness of the folding region 271 between the first folding surface area 273 and the second folding surface area 275 in a direction 202 of the substrate thickness 207 increases as a distance from a midline (e.g., fold plane 109) of the folding region 271 decreases. As used herein, the “local thickness” refers to a thickness measured in the direction 202 at a given location (in the direction 106) rather than an average distance between surfaces. In further aspects, the local thickness in the folding region 271 can vary from the central thickness 217 (e.g., at a boundary with the first transition region 212 and/or the second transition region 242) and substantially the substrate thickness 207 (e.g., at the fold plane 109—midline of the folding region 271). In further aspects, the local thickness of the folding region 271 as a function of the position in the direction 106 (e.g., along a folding width 274 of the folding region 271) is proportional to a cube root of a sine of a fractional position. In even further aspects, the fractional position is scaled to range from 0 (at one end of the folding region 271—boundary with the first transition region 212) to pi radians (at the other end of the folding region 271—boundary with the second transition region 242) across the folding width 274. As used herein, the “folding width” is measured as a distance in the direction 106 of the folding region 271 between a boundary with the first transition region 212 and the second transition region 242. In further aspects, as shown, the foldable substrate 201 can be symmetric about a plane equidistant from the first major surface 203 and the second major surface 205 (i.e., parallel to and equidistant from the first plane 204 and the second plane 206), and/or the foldable substrate 201 can be symmetric about a plane extending through a midline of the folding region 271 (e.g., fold plane 109) and equidistant from the first portion 221 and the second portion 231. In further aspects, as discussed below, the foldable substrate 201 can be folded into a folded configuration (see FIGS. 7-8) that is substantially circular (e.g., when folded about the midline of the folding region 271 (e.g., fold plane 109) in a Parallel Plat test, as described below) and/or a portion of the folded substrate that is bent in the folded configuration can be substantially equal to the folding width 274 of the folding region 271 (e.g., the folding width 274 can be substantially equal to about 1.6 times the minimum parallel plate distance of the foldable substrate 201 in a Parallel Plate test, as described below).

The inventors of the present application have determined that the thickness profile (e.g., profile of local thickness) of the folding region 271 described herein can unexpectedly enable the foldable substrate 201 to be folded into a substantially circular folded configuration (e.g., see FIGS. 7-8 and/or in a Parallel Plate Test). Without wishing to be bound by theory, a substrate with a uniform thickness in a region of the substrate being folded will have an elliptical folded configuration, which can have a folded length of the substrate of about 2.2 times the corresponding parallel plate distance as measured in the Parallel Plate Test (described below). In contrast, the substantially circular configuration of present disclosure can have a folded length of the foldable substrate of about 1.6 times the corresponding parallel plate distance. Additionally, the stress distribution in the folded configuration for a substrate with a uniform thickness is uneven, which can increase an incidence of damage and/or failure of the device relative to the stress distribution for folded foldable substrates with the thickness profile described herein.

Without wishing to be bound by theory, for a substrate subjected to a two-point bend (as in the Parallel Plate Test), the relationship between the change in position along the substrate(s) and the direction that the substrate is facing (0) is

$$\frac{ds}{d θ} = \sqrt{\frac{EI}{2 F sin {θ}^{′}}}$$

where E is the elastic modulus (e.g., Young's modulus), I is the moment of inertia for the cross-section of the substrate (perpendicular to the direction of the path s), and F is the applied bending force. For a rectangular cross-section, I=wh³/12, where w is the width of the substrate, and h is the thickness (or local thickness) of the substrate. In order to determine a local thickness profile to produce a constant change in the folded region (i.e., in a circular configuration with radius

$$R = \frac{ds}{d θ} ) ,$$

the expression can be rearranged as

$$h ( θ ) = \sqrt[3]{\frac{24 {R}^{2} F sin θ}{wE}} .$$

Then, the coordinate system can be changed from angular direction (θ) to cartesian coordinate (x) (e.g., in a direction of the parallel plate distance 711 shown in FIGS. 7-8) as

$$h ( x ) = \sqrt[3]{\frac{24 {R}^{2} F sin ( \frac{x}{R} + \frac{π}{2} )}{wE}} .$$

This profile is reflected in the folding region 271, shown in FIG. 2, as the local thickness profile between the first folding surface area 273 and the second folding surface area 275 (e.g., with each surface having half of the amplitude shown in the above equation. Also, as discussed below, the shape of the first folding surface area 373 excluding the plurality of teeth 311 is based on this profile.

As shown in FIGS. 2-3, the local thickness profile increases towards the fold plane 109. In contrast, conventional thickness profiles are either constant or decrease towards the fold plane. Unexpectedly, the increasing local thickness profile of the present disclosure enables the circular folded profile that decreases the length of the folded region and decreases stress concentrations along the bend.

FIG. 3 shows a cross-sectional view of the foldable apparatus 301 comprising a plurality of teeth 311 in accordance with aspects of the disclosure. In aspects, as shown in FIG. 3, the plurality of teeth 311 can extend from the first folding surface area 373, although the plurality of teeth can extend from both sides of the foldable substrate in further aspects. In further aspects, as shown, the folding region 271 including the plurality of teeth 311 is defined based on the local thickness profile of the first folding surface area 373 excluding the plurality of teeth 311, where the thickness increases from a local thickness equal to the central thickness (e.g., central thickness 217 shown in FIG. 2). In aspects, as shown in FIG. 3, a local thickness of the folding region 271 (e.g., profile of the first folding surface area 373) excluding the plurality of teeth 311 increases as a distance from a midline of the folding region 271 (e.g., fold plane 109) decreases. In further aspects, the local thickness (e.g., local thickness profile) of the folding region 271 as a function of the position along the folding width 274 of the folding region 271 is proportional to a cube root of a sine of a fractional position, as described above, with the fractional position scaled to range from 0 to pi radians across the folding width 274, as described above. In aspects, as shown, the folding region 271 is symmetric about a plane (e.g., fold plane 109) extending through the midline of the folding region 271 (e.g., equidistant from the first portion and the second portion). In aspects, as shown in FIG. 8, a folded configuration of the foldable substrate 201 folded about the midline of the folding region (e.g., fold plane 109 shown in FIG. 3) in a Parallel Plate Test (described below) is substantially circular. In aspects, as discussed above, the folding width 274 of the folding region 271 can be substantially equal to a minimum parallel plate distance 711 (see FIG. 8) of the foldable substrate 201 in a Parallel Plate Test (described below).

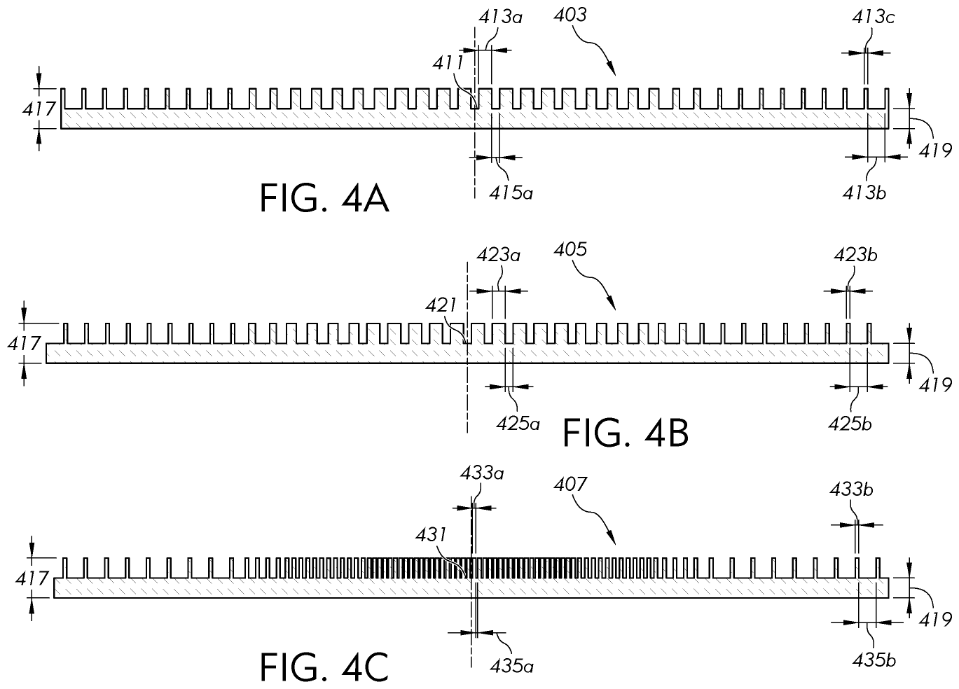

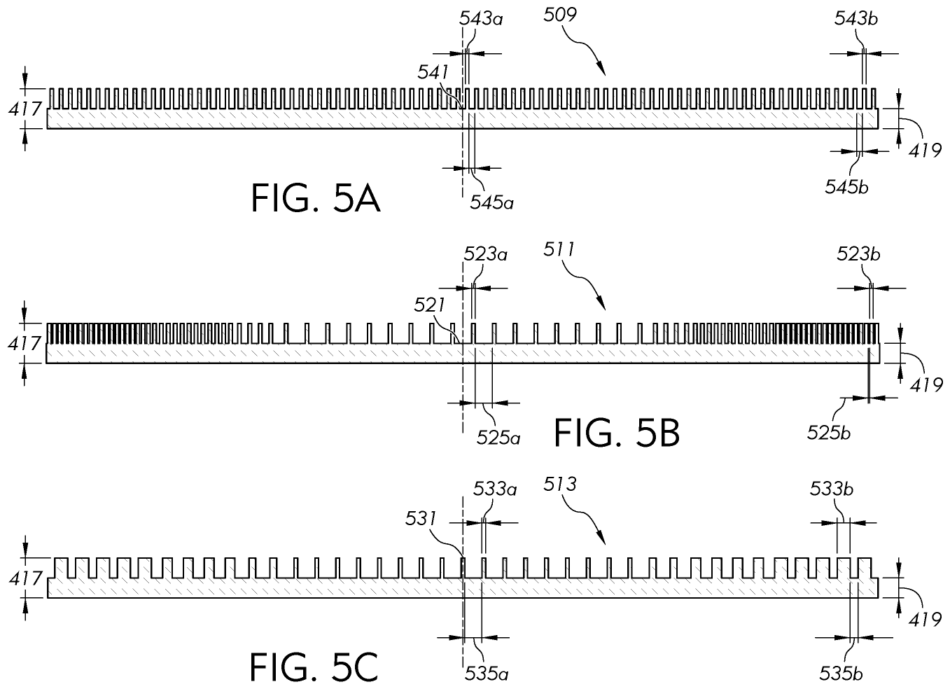

In aspects, as shown in FIG. 3, one or more of the teeth 313a-313e of the plurality of teeth 311 can comprise a local thickness substantially equal (e.g., within 5% or less) to the substrate thickness 207 (e.g., a surface of the one or more teeth can extend along the first plane 204), although local thickness of a tooth of the plurality of teeth can be less than the substrate thickness 207 in further aspects. In further aspects, as shown, all of the teeth 313a-313e of the plurality of teeth 311 can comprise substantially the same local thickness profile, which can, in even further aspects, comprise a local thickness 417 (see FIGS. 4A-4C and 5A-5C) substantially equal to the substrate thickness 207. In further aspects, as shown, the first folding surface area 373 can be opposite to a second folding surface area, which can be part of the second major surface 205, although the second folding surface area can be a mirror image of the first folding surface area or have the plurality of teeth in one of the patterns shown in FIG. 2, 4A-4C, or 5A-5C for the first folding surface area in further aspects. In aspects, as shown, the shape of a cross-section of one or more teeth 313a-313e of the plurality of teeth 311 can be substantially rectangular (e.g., linear), although the shape of the cross-section can be curved (e.g., elliptical), curvilinear, or a combination thereof in further aspects.

FIGS. 3, 4A-4C, and 5A-5C show various patterns for the plurality of grooves in foldable apparatus 301, 403, 405, 407, 509, 511, and/or 513, which can, for example, be combined with the shape of the first folding surface area 273 or 373 and/or second folding surface area 275 in some aspects. In aspects, as shown, one or more teeth (e.g., teeth 313a-313e) of the plurality of teeth comprise a width 315, 413a, 413c, 423a-b, 433a-b, 543a-b, 523a-b, and/or 533a-b. In further aspects, as shown in FIGS. 3, 4C, 5A, and 5B, the width 315, 433a-b, 543a-b, and/or 523a-b can be substantially the same for all of the teeth (e.g., of the plurality of teeth) in the folding region 271 and/or central portion 281. Alternatively, in further aspects, as shown in FIGS. 4A-4C and 5C, different teeth of the plurality of teeth can have widths that vary as the distance of the tooth from the midline changes. In even further aspects, as shown in FIGS. 4A-4B, the width 413a or 423a of a first tooth can be greater than a width 413c or 423b of a second tooth, where the first tooth is closer to the midline (e.g., dashed line, fold plane 109) than the second tooth is to the midline. For example, the width of different teeth can decrease (e.g., monotonically decrease) as a distance from the midline increases. Alternatively, in even further aspects, as shown in FIG. 5C, the width 533a of a first tooth can be less than the width 533b of a second tooth, where the first tooth is closer to the midline (e.g., dashed line, fold plane 109) than the second tooth is to the midline. For example, as shown, the width of different teeth can increase (e.g., monotonically increase) as a distance from the midline increases. In further aspects, the width of the one or more teeth can be about 10 μm or more, about 20 μm or more, about 30 μm or more, about 40 μm or more, about 50 μm or more, about 70 μm or more, about 100 μm or more, about 500 μm or less, about 300 μm or less, about 200 μm or less, about 100 μm or less, about 80 μm or less, about 60 μm or less, or about 40 μm or less. In further aspects, the width of the one or more teeth can be in a range from about 10 μm to about 500 μm, from about 10 μm to about 300 μm, from about 20 μm to about 200 μm, from about 30 μm to about 100 μm, from about 40 μm to about 80 μm, from about 40 μm to about 60 μm, or any range or subrange therebetween.

In aspects, as shown in FIGS. 3, 4A-4C, and 5A-5C, a distance 317, 415a-b, 425a-b, 435a-b, 545a-b, 525a-b, and/or 535a-b can be defined between an adjacent pair of teeth. For example, with reference to FIG. 3, groove 323b is between the adjacent pair of teeth 313c and 313d. Likewise, grooves 323a and 323c are adjacent to tooth 313a and 313e, respectively. In further aspects, as shown in FIGS. 3 and 5A, the distance 317 and 543a-b between an adjacent pair of teeth can be substantially the same for all adjacent pairs of teeth (e.g., of the plurality of teeth) in the folding region 271 and/or central portion 281. Alternatively, in further aspects, as shown in FIGS. 4A-4C and 5B-5C, distances between adjacent pairs of teeth for different adjacent pairs of teeth can be different as the distance of the adjacent pair of teeth from the midline changes. In even further aspects, as shown in FIGS. 4A-4C, the distance 415a, 425a, or 435a between a first adjacent pair of teeth can be less than a distance 413b, 425b, or 435b between a second adjacent pair of teeth, where the first adjacent pair of teeth is closer to the midline (e.g., dashed line, fold plane 109) than the second adjacent pair of teeth is to the midline. For example, the distance between adjacent pairs of teeth for different adjacent pairs of teeth can increase (e.g., monotonically increase) as the distance that the adjacent pair of teeth is from the midline increases. In even further aspects, as shown in FIGS. 5B-5C, the distance 525a or 435a between a first adjacent pair of teeth can be greater than a distance 525b or 535b between a second adjacent pair of teeth, where the first adjacent pair of teeth is closer to the midline (e.g., dashed line, fold plane 109) than the second adjacent pair of teeth is to the midline. For example, the distance between adjacent pairs of teeth for different adjacent pairs of teeth can decrease (e.g., monotonically decrease) as the distance that the adjacent pair of teeth is from the midline increases. In further aspects, the distance between an adjacent pair of teeth can be about 10 μm or more, about 20 μm or more, about 30 μm or more, about 40 μm or more, about 50 μm or more, about 70 μm or more, about 100 μm or more, about 500 μm or less, about 300 μm or less, about 200 μm or less, about 100 μm or less, about 80 μm or less, about 60 μm or less, or about 40 μm or less. In further aspects, the distance between an adjacent pair of teeth can be in a range from about 10 μm to about 500 μm, from about 10 μm to about 300 μm, from about 20 μm to about 200 μm, from about 30 μm to about 100 μm, from about 40 μm to about 80 μm, from about 40 μm to about 60 μm, or any range or subrange therebetween.

In aspects, as shown in FIGS. 3, 4A, 4B, 5A, and 5C, a pitch (e.g., pitch 319) (i.e., the sum of the width of a tooth and the distance between the tooth and another tooth as an adjacent pair of teeth) of the plurality of teeth (e.g., plurality of teeth 311) can be substantially the same for all teeth (e.g., of the plurality of teeth) in the folding region 271 and/or the central portion 281. In further aspects, as shown in FIGS. 3 and 5A, the pitch can be substantially the same by having a substantially uniform width of the teeth and a substantially uniform distance between adjacent pairs of teeth. Alternatively, in further aspects, as shown in FIGS. 4A, 4B, and 5C, the pitch can be substantially the same by having changes in the width of teeth offset by changes in the distance between adjacent pairs of teeth. In aspects, as shown in FIGS. 4C and 5B, a pitch of the plurality of teeth can change as a distance from the midline (e.g., fold plane 109) changes. For example, as shown in FIGS. 4C and 5B, the pitch can change by changing the distance between adjacent pairs of teeth, although the pitch can change by changing the widths of teeth. In further aspects, as shown in FIG. 4C, a pitch at a first location can be less than a pitch at a second location, where the first location is closer to the midline (e.g., fold plane 109) than the second location is to the midline. For example, the pitch of the plurality of teeth can increase (e.g., monotonically increase) as a distance from the midline (e.g., fold plane 109) increases. Alternatively, in further aspects, as shown in FIG. 5B, a pitch at a first location can be greater than a pitch at a second location, where the first location is closer to the midline (e.g., fold plane 109) than the second location is to the midline. For example, the pitch of the plurality of teeth can decrease (e.g., monotonically decrease) as a distance from the midline (e.g., fold plane 109) increases. In aspects, the pitch can be about 20 μm or more, about 30 μm or more, about 40 μm or more, about 50 μm or more, about 70 μm or more, about 100 μm or more, about 150 μm or more, 200 μm or more, about 1,000 μm or less, about 800 μm or less, about 600 μm or less, about 500 μm or less, about 300 μm or less, about 200 μm or less, about 100 μm or less, about 80 μm or less, about 60 μm or less, or about 40 μm or less. In aspects, the pitch can be in a range from about 20 μm to about 1,000 μm, from about 20 μm to about 800 μm, from about 30 μm to about 600 μm, from about 40 μm to about 500 μm, from about 50 μm to about 300 μm, from about 70 μm to about 200 μm, from about 150 μm to about 200 μm, or any range or subrange therebetween.

In aspects, as shown in FIGS. 3 and 4A-4C, the midline (e.g., dashed line, fold plane 109) may not impinge a tooth of the plurality of teeth (i.e., a location 411, 421, or 431 impinged by the midline is not a tooth). Alternatively, in aspects, as shown in FIGS. 5A-5C, the midline (e.g., dashed line, fold plane 109) may impinge a tooth of the plurality of teeth (i.e., a location 541, 521, or 531 impinged by the midline is a tooth). As discussed below with reference to the Examples, providing a plurality of grooves arranged such that there is not a tooth of the plurality of teeth impinged by the midline can decrease a bend-induced stress on the foldable substrate. In aspects, as shown in FIGS. 4A-4C and 5A-5C, a minimum thickness 419 of the foldable substrate (e.g., foldable apparatus 403, 405, 407, 509, 511, and/or 513) can be substantially equal to the central thickness 217.

In aspects, although not shown, a cross-sectional shape of a tooth of the plurality of teeth can be rounded (e.g., at the top rather than the angular corners shown herein). Providing rounded corners for the cross-sectional shape of a tooth of the plurality of teeth can decrease stress concentrations at the corners of the teeth, which can decrease a maximum bending stress associated with folding to a predetermined parallel plate distance and/or increase a reliability of folding the foldable substrate and/or foldable apparatus. Also, providing a plurality of teeth (e.g., comprising substantially the substrate thickness) can increase a puncture resistance of the folding region (e.g., due to the increased thickness of the plurality of teeth relative to the first folding surface area 373) while the folding region (excluding the teeth) can comprise the increasing local thickness profile discussed above that can facilitate folding into the substantially circular folded configuration. In aspects, although not shown, a local thickness of the first folding surface area 373 between adjacent pairs of teeth can be substantially constant (like that shown in FIGS. 4A-4C and 5A-5C instead of sloped in FIG. 3) while the local thickness profile (excluding the plurality of teeth) can still increase as a distance from the midline (e.g., fold plane 109) increases (e.g., approximate the cube root of a sine profile discussed above) as a step-wise thickness profile (with the average and substantially constant local thickness between adjacent pair of teeth having different values of the local thickness based on how far the adjacent pair of teeth are from the midline). In further aspects, providing a plurality of substantially constant local thicknesses between corresponding adjacent pairs of teeth of the plurality of teeth can simplify manufacturing, for example, enabling the local thickness between an adjacent pair of teeth to be formed in a single etching step (e.g., with the portions corresponding to the adjacent pair of teeth being masked).

A minimum force may be used to achieve a predetermined parallel plate distance with the foldable apparatus and/or foldable substrate. The parallel plate apparatus 701 of FIGS. 7-8, described above, is used to measure the “bend force” of a foldable apparatus and/or foldable substrate in accordance of the disclosure in the Parallel Plate Test. The force to go from a flat configuration (e.g., see FIGS. 2-3) to a bent (e.g., folded) configuration (e.g., see FIGS. 7-8) comprising the predetermined parallel plate distance is measured. In aspects, an bend force comprising the minimum force to bend the foldable apparatus and/or the foldable substrate from a flat configuration to a parallel plate distance of 6 mm (e.g., when a maximum thickness of the foldable substrate is about 70 μm or more) can be about 0.24 Newtons per millimeter width of the foldable substrate (N/mm) or less, about 0.22 N/mm or less, about 0.20 N/mm or less, about 0.18 N/mm or less, about 0.01 N/mm or more, about 0.05 N/mm or more, about 0.10 N/mm or more, or about 0.15 N/mm or more. In aspects, a bend force comprising the minimum force to bend the foldable apparatus and/or the foldable substrate from a flat configuration to a parallel plate distance of 6 mm (e.g., when a maximum thickness of the foldable substrate is about 70 μm or more) can be in a range from about 0.01 N/mm to about 0.24 N/mm, from about 0.05 N/mm to about 0.22 N/mm, from about 0.10 N/mm to about 0.20 N/mm, from about 0.15 N/mm to about 0.18 N/mm, or any range or subrange therebetween. In aspects, a bend force a foldable substrate comprising a thickness profile associated with a first folding surface area in accordance with aspects of the present disclosure with a maximum thickness can be lower than a comparative bend force of a substrate with a uniform thickness equal to the maximum thickness at the same parallel plate distance (e.g., 6 mm) by 20% or more, 25% or more, or 30% or more, for example, in a range from about 20% to about 75%, from about 25% to about 50%, or from about 30% to about 40%, or any range or subrange therebetween.

Aspects of the disclosure can comprise a consumer electronic product. The consumer electronic product can comprise a front surface, a back surface, and side surfaces. The consumer electronic product can further comprise electrical components at least partially within the housing. The electrical components can comprise a controller, a memory, and a display. The display can be at or adjacent to the front surface of the housing. The display can comprise liquid crystal display (LCD), an electrophoretic displays (EPD), an organic light-emitting diode (OLED) display, or a plasma display panel (PDP). The consumer electronic product can comprise a cover substrate disposed over the display. In aspects, at least one of a portion of the housing or the cover substrate comprises the foldable apparatus discussed throughout the disclosure. The consumer electronic product can comprise a portable electronic device, for example, a smartphone, a tablet, a wearable device, or a laptop.

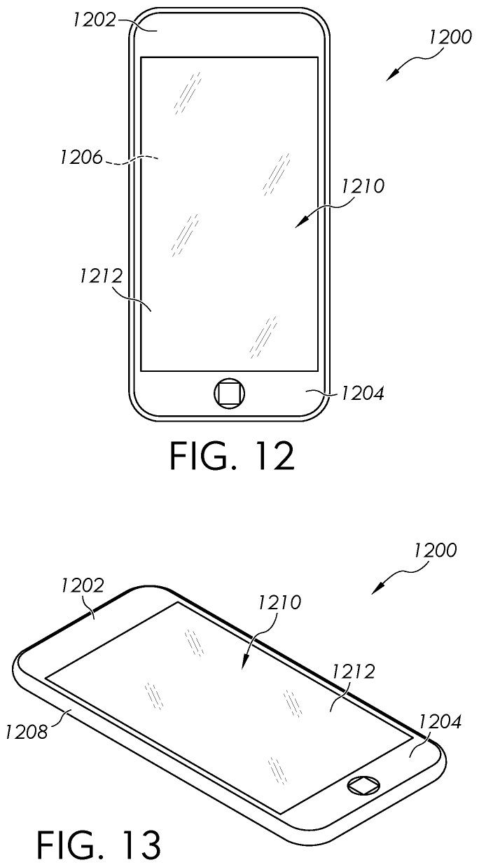

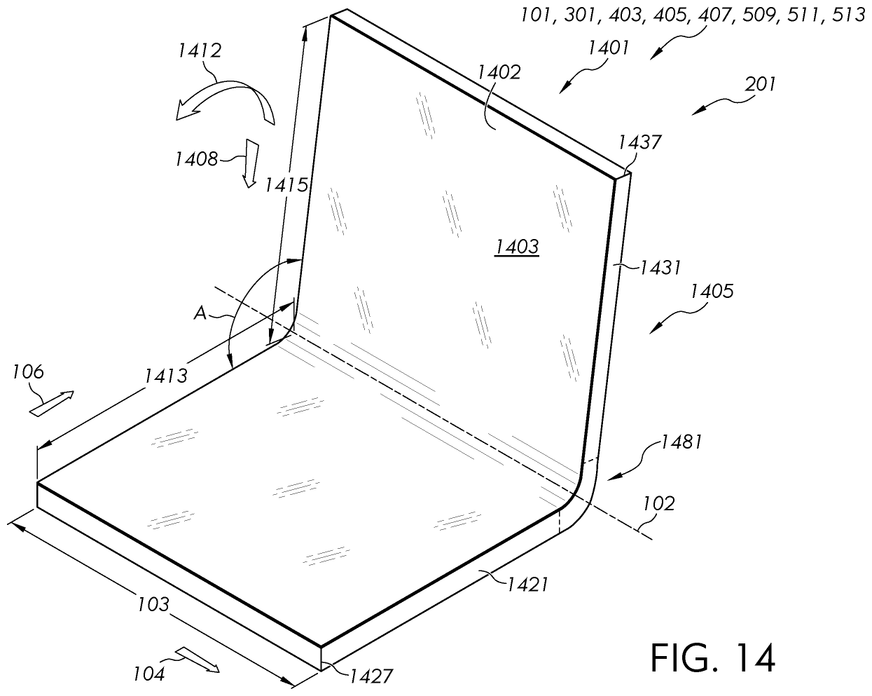

The foldable apparatus disclosed herein may be incorporated into another article, for example, an article with a display (or display articles) (e.g., consumer electronics, including mobile phones, tablets, computers, navigation systems, wearable devices (e.g., watches), and the like), architectural articles, transportation articles (e.g., automotive, trains, aircraft, sea craft, etc.), appliance articles, or any article that may benefit from some transparency, scratch-resistance, abrasion resistance or a combination thereof. An exemplary article incorporating any of the foldable apparatus disclosed herein is shown in FIGS. 12-13. Specifically, FIGS. 12-13 show a consumer electronic device 1200 including a housing 1202 having front 1204, back 1206, and side surfaces 1208. Although not shown, the consumer electronic device can comprise electrical components that are at least partially inside or entirely within the housing. For example, electrical components include at least a controller, a memory, and a display. As shown in FIGS. 12-13, the display 1210 can be at or adjacent to the front surface of the housing 1202. The consumer electronic device can comprise a cover substrate 1212 at or over the front surface of the housing 1202 such that it is over the display 1210. In aspects, at least one of the cover substrate 1212 or a portion of housing 1202 may include any of the foldable apparatus disclosed herein, for example, the foldable substrate.

Also, FIG. 14 schematically shows a perspective view of a consumer electronic product 1401 that is foldable. The consumer electronic product 1401 can include the foldable apparatus 101, 301, 403, 405, 407, 509, 511, and/or 513 and/or the foldable substrate 201 in accordance with aspects of the present disclosure. As shown, the consumer electronic product 1401 can include a front surface 1403 and a side surface 1405. The consumer electronic product 1401 can include electronic components, including a display 1402 that can be viewed through the front surface 1403 and/or at the front surface 1403. In aspects, as shown, the consumer electronic product 1401 can be folded in a direction 1412 to form a folded configuration that brings a first end 1427 and a second end 1437 (opposite the first end 1427) closer together (than in the unfolded configuration). Additionally, as shown, the consumer electronic product 1401 can be folded so that the front surface 1403 and/or display 1402 faces itself, although the consumer electronic product could be folded opposite the direction 1412 so that the front surface 1403 is on the outside of the consumer electronic product in the folded configuration. As discussed above with reference to FIG. 1, the consumer electronic product 1401 shown in FIG. 14 can be folded about the fold axis 102, where a central portion 1481 is located. The central portion 1481 can include the central portion 281 and/or the folding region 271 (e.g., of the foldable apparatus 101 and/301 discussed above with reference to FIGS. 2-3. As shown in FIG. 14, the central portion is positioned between a first portion 1421 including the first end 1427 and a second portion 1431 including the second end 1437. A location of the fold axis 102 can determine a first distance 1413 between the first end 1427 and the fold axis 102 (e.g., in direction 106) relative to a second distance 1415 between the second end 1437 and the fold axis 102 (e.g., in direction 1408). A total length of the consumer electronic product (e.g., length 105 in FIG. 1) can be the sum of the first distance 1413 and the second distance 1415). Also, as shown, the consumer electronic product is depicted as being in a folded or partially folded configuration with an angle A formed by front surface 1403 about the fold axis 102.

In aspects, the foldable substrate 201 comprising a glass-based substrate and/or a ceramic-based substrate can comprise one or more compressive stress regions. In aspects, a compressive stress region may be created by chemically strengthening. Chemically strengthening may comprise an ion exchange process, where ions in a surface layer are replaced by—or exchanged with—larger ions having the same valence or oxidation state. Methods of chemically strengthening will be discussed later. Without wishing to be bound by theory, chemically strengthening the first portion 221, the second portion 231, the central portion 281, and/or the folding region 271 can enable good impact and/or puncture resistance (e.g., resists failure for a pen drop height of about 15 centimeters (cm) or more, about 20 cm or more, about 50 cm or more). Without wishing to be bound by theory, chemically strengthening the first portion 221, the second portion 231, the central portion 281 and/or the folding region 271 can enable small (e.g., smaller than about 10 mm or less, about 5 mm or less, or about 3 mm or less) bend radii because the compressive stress from the chemical strengthening can counteract the bend-induced tensile stress on the outermost surface of the substrate. A compressive stress region may extend into a portion of the first portion and/or the second portion for a depth called the depth of compression (DOC). As used herein, depth of compression means the depth at which the stress in the chemically strengthened substrates and/or portions described herein changes from compressive stress to tensile stress. Depth of compression may be measured by a surface stress meter or a scattered light polariscope (SCALP, wherein values reported herein were made using SCALP-5 made by Glasstress Co., Estonia) depending on the ion exchange treatment and the thickness of the article being measured. Where the stress in the substrate and/or portion is generated by exchanging potassium ions into the substrate, a surface stress meter, for example, the FSM-6000 (Orihara Industrial Co., Ltd. (Japan)), is used to measure depth of compression. Unless specified otherwise, compressive stress (including surface CS) is measured by surface stress meter (FSM) using commercially available instruments, for example the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C770-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than about 400 μm, SCALP is used to measure the depth of compression and central tension (CT). Where the stress in the substrate and/or portion is generated by exchanging both potassium and sodium ions into the substrate and/or portion, and the article being measured is thicker than about 400 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF; the RNF method is described in U.S. Pat. No. 8,854,623, entitled “Systems and methods for measuring a profile characteristic of a glass sample”, which is incorporated herein by reference in its entirety) method also may be used to derive a graphical representation of the stress profile. When the RNF method is utilized to derive a graphical representation of the stress profile, the maximum central tension value provided by SCALP is utilized in the RNF method. The graphical representation of the stress profile derived by RNF is force balanced and calibrated to the maximum central tension value provided by a SCALP measurement. As used herein, “depth of layer” (DOL) means the depth that the ions have exchanged into the substrate and/or portion (e.g., sodium, potassium). Throughout the disclosure, DOL is measured in accordance with ASTM C-1422. Without wishing to be bound by theory, a DOL is usually greater than or equal to the corresponding DOC. Through the disclosure, when the maximum central tension cannot be measured directly by SCALP (as when the article being measured is thinner than about 400 μm) the maximum central tension can be approximated by a product of a maximum compressive stress and a depth of compression divided by the difference between the thickness of the substrate and twice the depth of compression, wherein the compressive stress and depth of compression are measured by FSM.

In aspects, the first portion 221 comprising the glass-based portion and/or ceramic-based portion may comprise a first compressive stress region at the first surface area 223 that can extend to a first depth of compression from the first surface area 223. In aspects, the first portion 221 comprising a first glass-based and/or ceramic-based portion may comprise a second compressive stress region at the second surface area 225 that can extend to a second depth of compression from the second surface area 225. In aspects, the first depth of compression and/or the second depth of compression as a percentage of the substrate thickness 207 can be about 5% or more, about 10% or more, about 12% or more, about 15% or more, about 30% or less, about 25% or less, about 22% or less, about 20% or less, about 17% or less, or about 15% or less. In aspects, the first depth of compression and/or the second depth of compression as a percentage of the substrate thickness 207 can be in a range from about 5% to about 30%, from about 10% to about 25%, from about 10% to about 22%, from about 12% to about 20%, from about 12% to about 17%, from about 15% to about 17%, or any range or subrange therebetween. In aspects, the first depth of compression and/or the second depth of compression can be about 1 μm or more, about 10 μm or more, about 15 μm or more, about 20 μm or more, about 25 μm or more, about 30 μm or more, about 200 μm or less, about 150 μm or less, about 100 μm or less, about 60 μm or less, about 45 μm or less, about 30 μm or less, or about 20 μm or less. In aspects, the first depth of compression and/or the second depth of compression can be in a range from about 1 μm to about 200 μm, from about 1 μm to about 150 μm, from about 10 μm to about 100 μm, from about 15 μm to about 600 μm, from about 20 μm to about 45 μm, from about 20 μm to about 30 μm, or any range or subrange therebetween. By providing a first portion comprising a first glass-based and/or ceramic-based portion comprising a first depth of compression and/or a second depth of compression in a range from about 1% to about 30% of the first thickness, good impact and/or puncture resistance can be enabled.

In aspects, the first compressive stress region can comprise a maximum first compressive stress. In aspects, the second compressive stress region can comprise a maximum second compressive stress. In further aspects, the maximum first compressive stress and/or the maximum second compressive stress can be about 100 MegaPascals (MPa) or more, about 300 MPa or more, 400 MPa or more, about 500 MPa or more, about 600 MPa or more, about 700 MPa or more, about 1,500 MPa or less, about 1,200 MPa or less, about 1,000 MPa or less, or about 800 MPa or less. In further aspects, the maximum first compressive stress and/or the maximum second compressive stress can be in a range from about 100 MPa to about 1,500 MPa, from about 100 MPa to about 1,200 MPa, from about 300 MPa to about 1,200 MPa, from about 300 MPa to about 1,000 MPa, from about 400 MPa to about 1,000 MPa, from about 500 MPa to about 1,000 MPa, from about 600 MPa to about 900 MPa, from about 700 MPa to about 800 MPa, or any range or subrange therebetween. By providing a maximum first compressive stress and/or a maximum second compressive stress in a range from about 100 MPa to about 1,500 MPa, good impact and/or puncture resistance can be enabled.

In aspects, the first portion 221 can comprise a first depth of layer of one or more alkali-metal ions associated with the first compressive stress region. In aspects, the first portion 221 can comprise a second depth of layer of one or more alkali-metal ions associated with the second compressive stress region and the second depth of compression. As used herein, the one or more alkali-metal ions of a depth of layer of one or more alkali-metal ions can include sodium, potassium, rubidium, cesium, and/or francium. In aspects, the one or more alkali ions of the first depth of layer of the one or more alkali ions and/or the second depth of layer of the one or more alkali ions comprises potassium. In aspects, the first depth of layer and/or the second depth of layer as a percentage of the substrate thickness 207 can be about 5% or more, about 10% or more, about 12% or more, about 15% or more, about 30% or less, about 25% or less, about 22% or less, about 20% or less, about 17% or less, or about 15% or less. In aspects, the first depth of layer and/or the second depth of layer as a percentage of the substrate thickness 207 can be in a range from about 5% to about 30%, from about 10% to about 25%, from about 10% to about 22%, from about 12% to about 20%, from about 12% to about 17%, from about 15% to about 17%, or any range or subrange therebetween. In aspects, the first depth of layer of the one or more alkali-metal ions and/or the second depth of layer of the one or more alkali-metal ions can be about 1 μm or more, about 10 μm or more, about 15 μm or more, about 20 μm or more, about 25 μm or more, about 30 μm or more, about 200 μm or less, about 150 μm or less, about 100 μm or less, about 60 μm or less, about 45 μm or less, about 30 μm or less, or about 20 μm or less. In aspects, the first depth of layer of the one or more alkali-metal ions and/or the second depth of layer of the one or more alkali-metal ions can be in a range from about 1 μm to about 200 μm, from about 1 μm to about 150 μm, from about 10 μm to about 100 μm, from about 15 μm to about 600 μm, from about 20 μm to about 45 μm, from about 20 μm to about 30 μm, or any range or subrange therebetween.

In aspects, the first portion 221 may comprise a first tensile stress region. In aspects, the first tensile stress region can be positioned between the first compressive stress region and the second compressive stress region. In aspects, the first tensile stress region can comprise a maximum first tensile stress. In further aspects, the maximum first tensile stress can be about 10 MPa or more, about 20 MPa or more, about 30 MPa or more, about 100 MPa or less, about 80 MPa or less, or about 60 MPa or less. In further aspects, the maximum first tensile stress can be in a range from about 10 MPa to about 100 MPa, from about 10 MPa to about 80 MPa, from about 10 MPa to about 60 MPa, from about 20 MPa to about 100 MPa, from about 20 MPa to about 80 MPa, from about 20 MPa to about 60 MPa, from about 30 MPa to about 100 MPa, from about 30 MPa to about 80 MPa, from about 30 MPa to about 60 MPa, or any range or subrange therebetween. Providing a maximum first tensile stress in a range from about 10 MPa to about 100 MPa can enable good impact and/or puncture resistance while providing low energy fractures, as discussed below.

In aspects, the second portion 231 comprising a second glass-based and/or ceramic-based portion may comprise a third compressive stress region at the third surface area 233 that can extend to a third depth of compression from the third surface area 233. In aspects, the second portion 231 comprising a second glass-based and/or ceramic-based portion may comprise a fourth compressive stress region at the fourth surface area 235 that can extend to a fourth depth of compression from the fourth surface area 235. In aspects, the third depth of compression and/or the fourth depth of compression as a percentage of the substrate thickness 207 can be within one or more of the ranges discussed above for the first depth of compression and/or the second depth of compression. In further aspects, the third depth of compression can be substantially equal to the fourth depth of compression. In aspects, the third depth of compression and/or the fourth depth of compression can be within one or more of the ranges discussed above for the first depth of compression and/or the second depth of compression. By providing a second portion comprising a glass-based and/or ceramic-based portion comprising a third depth of compression and/or a fourth depth of compression in a range from about 1% to about 30% of the substrate thickness, good impact and/or puncture resistance can be enabled.

In aspects, the third compressive stress region can comprise a maximum third compressive stress. In aspects, the fourth compressive stress region can comprise a maximum fourth compressive stress. In further aspects, the maximum third compressive stress and/or the maximum fourth compressive stress can be within one or more of the ranges discussed above for the maximum first compressive stress and/or the maximum second compressive stress. By providing a maximum third compressive stress and/or a maximum fourth compressive stress in a range from about 100 MPa to about 1,500 MPa, good impact and/or puncture resistance can be enabled.

In aspects, the second portion 231 can comprise a third depth of layer of one or more alkali-metal ions associated with the third compressive stress region and the third depth of compression. In aspects, the second portion 231 can comprise a fourth depth of layer of one or more alkali-metal ions associated with the fourth compressive stress region and the fourth depth of compression. In aspects, the one or more alkali ions of the third depth of layer of the one or more alkali ions and/or the fourth depth of layer of the one or more alkali ions comprises potassium. In aspects, the third depth of layer and/or the fourth depth of layer as a percentage of the substrate thickness 207 can be within one or more of the ranges discussed above for the first depth of layer and/or the second depth of layer as a percentage of the substrate thickness 207. In aspects, the third depth of layer of the one or more alkali-metal ions and/or the fourth depth of layer of the one or more alkali-metal ions can be the first depth of layer and/or the second depth of layer.

In aspects, the second portion 231 may comprise a second tensile stress region. In aspects, the second tensile stress region can be positioned between the third compressive stress region and the fourth compressive stress region. In aspects, the second tensile stress region can comprise a maximum second tensile stress. In further aspects, the maximum second tensile stress can be within one or more of the ranges discussed above for the maximum first tensile stress. In aspects, the maximum first tensile stress can be substantially equal to the maximum second tensile stress. Providing a maximum second tensile stress in a range from about 10 MPa to about 100 MPa can enable good impact and/or puncture resistance while providing low energy fractures, as discussed below.

In aspects, the first depth of compression can be substantially equal to the third depth of compression. In aspects, the second depth of compression can be substantially equal to the fourth depth of compression. In aspects, the maximum first compressive stress can be substantially equal to the maximum third compressive stress. In aspects, the maximum second compressive stress can be substantially equal to the maximum fourth compressive stress. In aspects, the first depth of layer of one or more alkali-metal ions can be substantially equal to the third depth of layer of one or more alkali-metal ions. In aspects, the second depth of layer of one or more alkali-metal ions can be substantially equal to the fourth depth of layer of one or more alkali-metal ions.

In aspects, the central portion 281 and/or the folding region 271 can one or more compressive stress regions. In further aspects, there can be a first folding compressive stress region extending to a first folding depth of compression from the first folding surface area 273, and/or there can be a second folding compressive stress region extending to a second folding depth of compression from the second folding surface area 275. In further aspects, the first folding compressive stress region and/or the second folding compressive stress region can be within the folding region 271 of the central portion 281 (e.g., coextensive with the first folding surface area 273 and/or the second folding surface area 275). In further aspects, the first folding depth of compression and/or the second folding depth of compression as a percentage of the central thickness 217 or the local thickness can be within one or more of the ranges discussed above for the first depth of compression and/or the second depth of compression as a percentage of the substrate thickness 207. In further aspects, the first folding depth of compression and/or the second folding depth of compression as a percentage of the central thickness 217 or the local thickness can be about 1% or more, about 2% or more, about 5% or more, about 8% or more, about 10% or more, about 12% or more, about 20% or less, about 17% or less, about 15% or less, about 12% or less, about 10% or less, about 7% or less, or about 5% or less. For example, the first folding depth of compression and/or the second folding depth of compression as a percentage of the central thickness 217 or the local thickness can be in a range from about 1% to about 20%, from about 2% to about 17%, from about 5% to about 15%, from about 7% to about 10%, or any range or subrange therebetween. In further aspects, the first folding depth of compression can be substantially equal to the second folding depth of compression. In further aspects, the first folding depth of compression and/or the second folding depth of compression can be within one or more of the ranges discussed above for the first depth of compression and/or the second depth of compression. In further aspects, the first folding depth of compression and/or the second folding depth of compression can be about 1 μm or more about 2 μm or more, about 4 μm or more, about 6 μm or more, about 20 μm or less, about 15 μm or less, about 10 μm or less, or about 8 μm or less. For example, the first folding depth of compression and/or the second folding depth of compression can be in a range from about 1 μm to about 20 μm, from about 2 μm to about 15 μm, from about 4 μm to about 10 μm, from about 6 μm to about 8 μm, or any range or subrange therebetween. By providing a central portion and/or folding region comprising a glass-based and/or ceramic-based portion comprising a first folding depth of compression and/or a second folding depth of compression in a range from about 1% to about 30% (e.g., from about 1% to about 20%) of the central thickness or local thickness, good impact and/or puncture resistance can be enabled.

In aspects, the first folding compressive stress region can comprise a maximum first folding compressive stress. In aspects, the second folding compressive stress region can comprise a maximum second folding compressive stress. In further aspects, the maximum first folding compressive stress and/or the maximum second folding compressive stress can be within one or more of the ranges discussed above for the maximum first compressive stress and/or the maximum second compressive stress. By providing a maximum first folding compressive stress and/or a maximum second folding compressive stress in a range from about 100 MPa to about 1,500 MPa, good impact and/or puncture resistance can be enabled.

In aspects, the central portion 281 and/or the folding region 271 can comprise a first folding depth of layer of one or more alkali-metal ions associated with the first folding compressive stress region and the first folding depth of compression. In aspects, the central portion 281 and/or the folding region 271 can comprise a second folding depth of layer of one or more alkali-metal ions associated with the second folding compressive stress region and the second folding depth of compression. In aspects, the one or more alkali ions of the first folding depth of layer of the one or more alkali ions and/or the second folding depth of layer of the one or more alkali ions comprises potassium. In aspects, the first folding depth of layer and/or the second folding depth of layer as a percentage of the central thickness 217 or the local thickness can be within one or more of the ranges discussed above for the first depth of layer and/or the second depth of layer as a percentage of the substrate thickness 207.

In aspects, the first folding depth of layer and/or the second folding depth of layer as a percentage of the central thickness 217 or the local thickness can be about 1% or more, about 2% or more, about 5% or more, about 8% or more, about 10% or more, about 12% or more, about 20% or less, about 17% or less, about 15% or less, about 12% or less, about 10% or less, about 7% or less, or about 5% or less. For example, the first folding depth of layer and/or the second folding depth of layer as a percentage of the central thickness 217 or the local thickness can be in a range from about 1% to about 20%, from about 2% to about 17%, from about 5% to about 15%, from about 7% to about 10%, or any range or subrange therebetween. In further aspects, the first folding depth of layer can be substantially equal to the second folding depth of layer. In further aspects, the first folding depth of layer and/or the second folding depth of layer can be within one or more of the ranges discussed above for the first depth of layer and/or the second depth of layer. In further aspects, the first folding depth of layer and/or the second folding depth of layer can be about 1 μm or more about 2 μm or more, about 4 μm or more, about 6 μm or more, about 20 μm or less, about 15 μm or less, about 10 μm or less, or about 8 μm or less. For example, the first folding depth of layer and/or the second folding depth of layer can be in a range from about 1 μm to about 20 μm, from about 2 μm to about 15 μm, from about 4 μm to about 10 μm, from about 6 μm to about 8 μm, or any range or subrange therebetween.

In aspects, the central portion 281 and/or the folding region 271 may comprise a folding tensile stress region. In aspects, the folding tensile stress region can be positioned between the first folding compressive stress region and the second folding compressive stress region. In aspects, the folding tensile stress region can comprise a maximum folding tensile stress. In further aspects, the maximum folding tensile stress can be about 125 MPa or more, about 150 MPa or more, about 200 MPa or more, about 375 MPa or less, about 300 MPa or less, or about 250 MPa or less. In further aspects, the maximum folding tensile stress can be in a range from about 125 MPa to about 375 MPa, from about 125 MPa to about 300 MPa, from about 125 MPa to about 250 MPa, from about 150 MPa to about 375 MPa, from about 150 MPa to about 300 MPa, from about 150 MPa to about 250 MPa, from about 200 MPa to about 375 MPa, from about 200 MPa to about 300 MPa, from about 200 MPa to about 250 MPa, or any range or subrange therebetween. Providing a maximum folding tensile stress in a range from about 125 MPa to about 375 MPa can enable low minimum bend radii.

FIGS. 6-8 schematically illustrate aspects of a foldable apparatus 601 and/or 801 in accordance with aspects of the disclosure in a folded configuration. As shown in FIG. 7, the foldable apparatus 601 is folded such that the second major surface 205 of the foldable substrate 201 is on the inside of the folded foldable apparatus 601, for example, foldable apparatus 101 can be folded to form foldable apparatus 601. For example, a display could be located on the side of the second major surface 205, and a viewer would view the display from the side of the first major surface 203. Alternatively, a display could be located on the side of the first major surface 203, and a viewer would view the display from the side of the second major surface 205. As shown in FIG. 8, the foldable apparatus 801 is folded such that the second major surface 205 of the foldable substrate 201 is on the inside of the folded foldable apparatus 801 for example, foldable apparatus 301 can be folded to form foldable apparatus 801. For example, a display could be located on the side of the second major surface 205, and a viewer would view the display from the side of the first major surface 203. Alternatively, a display could be located on the side of the first major surface 203, and a viewer would view the display from the side of the second major surface 205.

As used herein, “foldable” includes complete folding, partial folding, bending, flexing, or multiple capabilities. As used herein, the terms “fail,” “failure” and the like refer to breakage, destruction, delamination, or crack propagation. Likewise, a foldable apparatus achieves a parallel plate distance of “X,” or has a parallel plate distance of “X,” or comprises a parallel plate distance of “X” if it resists failure when the foldable apparatus is held at a parallel plate distance of “X” for 24 hours at about 85° C. and about 85% relative humidity.

As used herein, the “parallel plate distance” of a foldable apparatus and/or foldable substrate is measured with the following test configuration and process using a parallel plate apparatus 701 (see FIGS. 6-8) that comprises a pair of parallel rigid stainless-steel plates 703, 705 comprising a first rigid stainless-steel plate 703 and a second rigid stainless-steel plate 705. When measuring the “parallel plate distance” for the foldable substrate 201 (e.g., the foldable apparatus 101 and/or 301 shown in FIGS. 2-3 consisting of foldable substrate 201), as shown in FIGS. 7 and 8, the foldable substrate 201 is placed between the pair of plates 703 and 705 such that the first major surface 203 is in contact with the pair of plates 703 and 705. For determining a “parallel plate distance”, the distance between the parallel plates is reduced at a rate of 50 μm/second until the parallel plate distance 711 is equal to the “parallel plate distance” to be tested. Then, the parallel plates are held at the “parallel plate distance” to be tested for 24 hours at about 85° C. and about 85% relative humidity. As used herein, the “minimum parallel plate distance” is the smallest parallel plate distance that the foldable apparatus can withstand without failure under the conditions and configuration described above.

In aspects, the foldable apparatus 101, 301, 403, 405, 407, 509, 511, 513, 601 and/or 801 and/or foldable substrate 201 can achieve a parallel plate distance of 100 mm or less, 50 mm or less, 20 mm or less, 10 mm or less, 5 mm or less, 4 mm or less, 3 mm or less, 2 mm or less, or 1 mm or less. In further aspects, the foldable apparatus 101, 301, 403, 405, 407, 509, 511, 513, 601 and/or 801 and/or foldable substrate 201 can achieve a parallel plate distance of 50 millimeters (mm), or 20 mm, or 10 mm, 8 mm, 6 mm, 5 mm, 4 mm, 3 mm, 2 mm, or 1 mm. In aspects, the foldable apparatus 101, 301, 403, 405, 407, 509, 511, 513, 601 and/or 801 and/or foldable substrate 201 can comprise a minimum parallel plate distance of about 40 mm or less, about 20 mm or less, about 10 mm or less, about 8 mm or less, about 6 mm or less, about 5 mm or less, about 4 mm or less, about 3 mm or less, about 2 mm or less, about 1 mm or less, about 1 mm or more, about 2 mm or more, about 3 mm or more, about 4 mm or more, about 5 mm or more, or about 10 mm or more. In aspects, the foldable apparatus 101, 301, 403, 405, 407, 509, 511, 513, 601 and/or 801 and/or foldable substrate 201 can comprise a minimum parallel plate distance in a range from about 1 mm to about 40 mm, from about 1 mm to about 20 mm, from about 1 mm to about 10 mm, from about 1 mm to about 5 mm, from about 2 mm to about 3 mm, or any range or subrange therebetween. In aspects, the foldable apparatus 101, 301, 403, 405, 407, 509, 511, 513, 601 and/or 801 and/or foldable substrate 201 can achieve a minimum parallel plate distance in a range from about 2 mm to about 40 mm, from about 2 mm to about 20 mm, from about 2 mm to about 10 mm, from about 3 mm to about 10 mm, from about 3 mm to about 8 mm, from about 3 mm to about 6 mm, from about 4 mm to about 5 mm, or any range or subrange therebetween.

In aspects, the folding width 274 of the folding region 271 of the foldable substrate 201 can be about 1 time or more, about 1.1 times or more, about 1.3 times or more, about 1.5 times or more, about 1.6 times or more, about 1.8 times or more, about 2 times or more, about 2.2 times or more, about 3 times or less, about 2.5 times or less, about 2 times or less, about 1.8 times or less, or about 1.5 times or less the minimum parallel plate distance. In aspects, the folding width 274 of the folding region 271 of the foldable substrate 201 as a multiple of the minimum parallel plate distance can be in a range from about 1 time to about 3 times, from about 1.1 times to about 2.5 times, from about 1.3 times to about 2.2 times, from about 1.5 times to about 2 times, from about 1.6 times to about 1.8 times, or any range or subrange therebetween. Without wishing to be bound by theory, the length of a folded portion in a circular configuration between parallel plates can be about 1.6 times the parallel plate distance 711. Without wishing to be bound by theory, the length of a bend portion in an elliptical configuration between parallel plates can be about 2.2 times the parallel plate distance 711. In aspects, the folding width 274 of the folding region 271 of the foldable substrate 201 can be about 1 mm or more, about 3 mm or more, about 5 mm or more, about 6 mm or more, about 8 mm or more, about 10 mm or more, about 15 mm or more, about 20 mm or more, about 100 mm or less, about 60 mm or less, about 50 mm or less, about 40 mm or less, about 35 mm or less, about 30 mm or less, about 25 mm or less, about 20 mm or less, about 15 mm or less, or about 10 mm or less. In aspects, the folding width 274 of the folding region 271 of the foldable substrate 201 can be in a range from about 1 mm to about 100 mm, from about 2 mm to about 60 mm, from about 3 mm to about 50 mm, from about 5 mm to about 40 mm, from about 6 mm to about 35 mm, from about 6 mm to about 30 mm, from about 8 mm to about 25 mm, from about 8 mm to about 20 mm, from about 10 mm to about 15 mm, or any range of subrange therebetween. By providing a folding width within the above-noted ranges in this paragraph (, folding of the foldable apparatus without failure can be facilitated.

As used herein, a central width of the central portion 281 of the foldable substrate 201 is defined between the first portion 221 and the second portion 231 in the direction 106 of the length 105. In aspects, the central width of the central portion 281 of the foldable substrate 201 can extend from the first portion 221 to the second portion 231. In aspects, the central width of the central portion 281 of the foldable substrate 201 can be about 1.4 times or more, about 1.6 times or more, about 2 times or more, about 2.2 times or more, about 3 times or less, or about 2.5 times or less the minimum parallel plate distance. In aspects, the central width of the central portion 281 of the foldable substrate 201 as a multiple of the minimum parallel plate distance can be in a range from about 1.4 times to about 3 times, from about 1.6 times to about 3 times, from about 1.6 times to about 2.5 times, from about 2 times to about 2.5 times, from about 2.2 times to about 2.5 times, from about 2.2 times to about 3 times, or any range or subrange therebetween. In aspects, the central width of the central portion 281 of the foldable substrate 201 can be about 1 mm or more, about 3 mm or more, about 5 mm or more, about 8 mm or more, about 10 mm or more, about 15 mm or more, about 20 mm or more, about 100 mm or less, about 60 mm or less, about 50 mm or less, about 40 mm or less, about 35 mm or less, about 30 mm or less, or about 25 mm or less. In aspects, the central width of the central portion 281 of the foldable substrate 201 can be in a range from about 1 mm to about 100 mm, from about 3 mm to about 100 mm, from about 3 mm to about 60 mm, from about 5 mm to about 60 mm, from about 5 mm to about 50 mm, from about 8 mm to about 50 mm, from about 8 mm to about 40 mm, from about 10 mm to about 40 mm, from about 10 mm to about 35 mm, from about 15 mm to about 35 mm, from about 15 mm to about 30 mm, from about 20 mm to about 30 mm, from about 20 mm to about 25 mm, or any range of subrange therebetween. In aspects, the central width of the central portion 281 of the foldable substrate 201 can be about 2.8 mm or more, about 6 mm or more, about 9 mm or more, about 60 mm or less, about 40 mm, or less, or about 24 mm or less. In aspects, the central width of the central portion 281 of the foldable substrate 201 can be in a range from about 2.8 mm to about 60 mm, from about 2.8 mm to about 40 mm, from about 2.8 mm to about 24 mm, from about 6 mm to about 60 mm, from about 6 mm to about 40 mm, from about 6 mm to about 24 mm, from about 9 mm to about 60 mm, from about 9 mm to about 40 mm, from about 9 mm to about 24 mm, or any range of subrange therebetween. By providing a width within the above-noted ranges in this paragraph, folding of the foldable apparatus without failure can be facilitated.

In aspects, the central width of the central portion 281 as a percentage of the length 105 of the foldable apparatus can be about 30% or more, about 35% or more, about 40% or more, about 45% or more, about 70% or less, about 60% or less, about 55% or less, or about 50% or less. In aspects, the central width of the central portion 281 as a percentage of the length 105 of the foldable apparatus can range from about 30% to about 70%, from about 35% to about 60%, from about 40% to about 55%, from about 45% to about 50%, or any range or subrange therebetween. In aspects, the central width of the central portion 281 can be about 30 mm or more, about 35 mm or more, about 40 mm or more, about 45 mm or more, about 50 mm or more, about 100 mm or less, about 80 mm or less, about 70 mm or less, or about 60 mm or less. In aspects, the central width of the central portion 281 can range from about 30 mm to about 100 mm, from about 35 mm to about 80 mm, from about 40 mm to about 70 mm, from about 45 mm to about 60 mm, from about 50 mm to about 60 mm, or any range or subrange therebetween.

In aspects, the foldable substrate and/or the foldable apparatus can be rollable. As used herein, a foldable substrate or a foldable apparatus is “rollable” if it can achieve a threshold parallel plate distance over a length of the corresponding foldable substrate and/or foldable apparatus that is the greater of 10 mm or 10% of the length of the corresponding foldable substrate and/or foldable apparatus. For example, as shown in FIG. 37, the foldable substrate 201 is considered “rollable” when the folding width 274 of the folding region 271 and/or the central width of the central portion 281 is greater than 10% of the length 105 (see FIG. 1) extending in the direction 106 of the length 105.

The foldable apparatus 101, 301, 403, 405, 407, 509, 511, 513, 601 and/or 801 may have an impact resistance defined by the capability of a region of the foldable apparatus (e.g., a region comprising the first portion 221, a region comprising the second portion 231, a region comprising the folding region 271 and/or central portion 281) to avoid failure at a pen drop height (e.g., 5 centimeters (cm) or more, 10 centimeters or more, 20 cm or more), when measured according to the “Pen Drop Test.” As used herein, the “Pen Drop Test” is conducted such that samples of foldable apparatus are tested with the load (i.e., from a pen dropped from a certain height) imparted to an outer major surface (e.g., first major surface 203 or second major surface 205 of the foldable substrate 201 for foldable apparatus 101 or 301 shown in FIGS. 2-3) with the foldable apparatus configured with a 100 μm thick sheet of PET attached to a test adhesive layer having a thickness of 50 μm that is in turn attached to the surface of the foldable substrate opposite the outer major surface to be impinged by the pen. As such, the PET layer in the Pen Drop Test is meant to simulate a foldable electronic display device (e.g., an OLED device). During testing, the foldable apparatus bonded to the PET layer is placed on an aluminum plate (6063 aluminum alloy, as polished to a surface roughness with 400 grit paper) with the PET layer in contact with the aluminum plate. No tape is used on the side of the sample resting on the aluminum plate.

A tube is used for the Pen Drop Test to guide a pen to an outer surface of the foldable apparatus. For the foldable apparatus 101, 301, 403, 405, 407, 509, 511, 513, 601 and/or 801, the pen is guided to the outer major surface (e.g., first major surface 203 or second major surface 205 of the foldable substrate 201 for foldable apparatus 101 or 301 shown in FIGS. 2-3), and the tube is placed in contact with the second major surface 205 of the foldable substrate 201 so that the longitudinal axis of the tube is substantially perpendicular to the outer major surface with the longitudinal axis of the tube extending in the direction of gravity. The tube has an outside diameter of 1 inch (2.54 cm), an inside diameter of nine-sixteenths of an inch (1.4 cm), and a length of 90 cm. An acrylonitrile butadiene (ABS) shim is employed to hold the pen at a predetermined height for each test. After each drop, the tube is relocated relative to the sample to guide the pen to a different impact location on the sample. The pen employed in Pen Drop Test is a BIC Easy Glide Pen, Fine, having a tungsten carbide ballpoint tip of 0.7 mm (0.68 mm) diameter, and a weight of 5.73 grams (g) including the cap.

For the Pen Drop Test, the pen is dropped with the cap attached to the top end (i.e., the end opposite the tip) so that the ballpoint can interact with the test sample. In a drop sequence according to the Pen Drop Test, one pen drop is conducted at an initial height of 1 cm, followed by successive drops in 0.5 cm increments up to 20 cm, and then after 20 cm, 2 cm increments until failure of the test sample. After each drop is conducted, the presence of any observable fracture, failure, or other evidence of damage to the sample is recorded along with the particular pen drop height. Using the Pen Drop Test, multiple samples can be tested according to the same drop sequence to generate a population with improved statistical accuracy. For the Pen Drop Test, the pen is to be changed to a new pen after every 5 drops, and for each new sample tested. In addition, all pen drops are conducted at random locations on the sample at or near the center of the sample, with no pen drops near or on the edge of the samples.

For purposes of the Pen Drop Test, “failure” means the formation of a visible mechanical defect in a laminate. The mechanical defect may be a crack or plastic deformation (e.g., surface indentation). The crack may be a surface crack or a through crack. The crack may be formed on an interior or exterior surface of a laminate. The crack may extend through all or a portion of the foldable substrate 201 and/or coating. A visible mechanical defect has a minimum dimension of 0.2 mm or more.

In aspects, the foldable apparatus can resist failure for a pen drop in a region comprising the first portion 221 or the second portion 231 at a pen drop height of 10 centimeters (cm), 12 cm, 14 cm, 16 cm, or 20 cm. In aspects, a maximum pen drop height that the foldable apparatus can withstand without failure over a region comprising the first portion 221 or the second portion 231 may be about 10 cm or more, about 12 cm or more, about 14 cm or more, about 16 cm or more, about 40 cm or less, or about 30 cm or less, about 20 cm or less, about 18 cm or less. In aspects, a maximum pen drop height that the foldable apparatus can withstand without failure over a region comprising the first portion 221 or the second portion 231 can be in a range from about 10 cm to about 40 cm, from about 12 cm to about 40 cm, from about 12 cm to about 30 cm, from about 14 cm to about 30 cm, from about 14 cm to about 20 cm, from about 16 cm to about 20 cm, from about 18 cm to about 20 cm, or any range or subrange therebetween.

In aspects, the foldable apparatus can resist failure for a pen drop in the central portion 281 and/or folding region 271 (e.g., between the first portion 221 and the second portion 231) at a pen drop height of 1 cm, 2 cm, 3 cm, 4 cm, 5 cm, or more. In aspects, a maximum pen drop height that the foldable apparatus can withstand without failure over the central portion 281 and/or folding region 271 (e.g., between the first portion 221 and the second portion 231) may be about 1 cm or more, about 2 cm or more, about 3 cm or more, about 4 cm or more, about 20 cm or less, about 10 cm or less, about 8 cm or less, or about 6 cm or less. In aspects, a maximum pen drop height that the foldable apparatus can withstand without failure over the central portion 281 and/or folding region 271 (e.g., between the first portion 221 and the second portion 231) can be in a range from about 1 cm to about 20 cm, from about 2 cm to about 20 cm, from about 2 cm to about 10 cm, from about 3 cm to about 10 cm, from about 3 cm to about 8 cm, from about 4 cm to about 8 cm, from about 4 cm to about 6 cm, or any range or subrange therebetween. In aspects, a maximum pen drop height that the foldable apparatus can withstand without failure of the central portion 281 and/or folding region 271 (e.g., between the first portion 221 and the second portion 231) can be in a range from about 1 cm to about 10 cm, from about 1 cm to about 8 cm, from about 1 cm to about 5 cm, from about 2 cm to about 5 cm, from about 3 cm to about 5 cm, from about 4 cm to about 5 cm, or any range or subrange therebetween.

Aspects of making foldable substrates of the present disclosure will now be discussed. In aspects, an initial substrate (e.g., monolithic substrate) may be provided by purchase or otherwise obtaining a substrate or by forming the foldable substrate. In aspects, the initial substrate can comprise a glass-based substrate and/or a ceramic-based substrate. In further aspects, glass-based substrates and/or ceramic-based substrates can be provided by forming them with a variety of ribbon forming processes, for example, slot draw, down-draw, fusion down-draw, up-draw, press roll, redraw, or float. In further aspects, ceramic-based substrates can be provided by heating a glass-based substrate to crystallize one or more ceramic crystals.

In aspects, the foldable substrates 403, 405, 407, 509, 511, and/or 513 shown in FIGS. 4A-4C and/or 5A-5C can be formed by applying a patterned etch mask with the location and length of portions of the patterned etch mask being proportional to the width of the corresponding teeth of the plurality of teeth in the resulting foldable substrate to form a masked surface. Then, the masked surface can be etched (e.g., using a mineral acid, using a plasma dry etching) to form the first folding surface area with associated recesses defining the plurality of teeth. Alternatively, instead of etching, the plurality of teeth can be defined using a laser (e.g., laser etching or laser ablation) to form the first folding surface area with the plurality of teeth corresponding to untreated portions of the surface.

In aspects, the foldable substrate 301 shown in FIG. 3 can be formed by sequentially etching portions of the substrate. For portions of the initial substrate corresponding to portion of the first folding surface area 373 having substantially the same thickness can be exposed while the rest of the corresponding surface is masked (e.g., a uniform etch mask can be patterned using photolithography or a laser to expose the portions to be etched). For example, the exposed portions can correspond to the portions with the greatest difference between the first folding surface area 373 and a top surface of the teeth-first major surface 203). The exposed portions can be etched (e.g., using a mineral acid, using a plasma dry etching) to form the corresponding portions of the first folding surface area 373. Then, the etched portions are masked (e.g., subsequently coated with a masking material while remaining the etch mask is kept in place, or removing the etch mask and reapplying a new etch mask) and another portion of the first folding surface area 373 corresponding to another substantially constant thickness can be exposed (e.g., using photolithography or using a laser to expose the portions to be etched) with the exposed portions being etched to form the next set of portions of the first folding surface area 373. This can be repeated as needed until the first folding surface area 373 and the plurality of teeth are formed.

Alternatively, another method of forming the foldable substrate 301 shown in FIG. 3 by sequentially etching portions of the substrate will now be discussed. An initial patterned etch mask can be formed on a surface of the initial substrate with the location and/or length of portions of the initial patterned etch mask proportional to the corresponding proportions (e.g., width, aspect ratio) and/or spacing of the resulting teeth of the plurality of teeth (e.g., a uniform etch mask can be patterned using photolithography or a laser to expose the portions to be etched). The surface can be etched until the shallowest portion (e.g., greatest local thickness) of the first folding surface area 373 is formed. Then, those portions corresponding to the predetermined local thickness of the first folding surface area 373 are masked (e.g., modifying the initial patterned etch mask, for example, by disposing a masking material in the plurality of recesses corresponding to the location of the portions with the predetermined local thickness) and then the surface is etched until the next shallowest portions of the first folding surface area 373 is formed. This can be repeated as needed until the first folding surface area 373 and the plurality of teeth are formed.

Alternatively, yet another method of forming the foldable substrate 301 shown in FIG. 3 by sequentially etching portions of the substrate will now be discussed. An initially patterned etch mask can be formed on a surface of the initial substrate. Exposed portions (between portions of the initially patterned mask) can correspond to portion of the first folding surface area 373 having the thinnest (e.g., smallest) local thickness (e.g., greatest difference between the resulting first major surface 203 and a local thickness of the first folding surface area 373). The surface with the initially patterned etch mask is etched until the etched thickness is equal to a difference between the target local thickness and the next thinnest local thickness of the first folding surface area 373. Then, initially patterned etch mask is further patterned (e.g., using a laser, using plasma) to reveal portions of the surface corresponding to the next thinnest local thickness of the first folding surface area 373, and the surface with the further patterned etch mask is etched until a difference between the target thickness of newly added portion and the next thinnest local thickness of the first folding surface area 373. This can be repeated as needed until the first folding surface area 373 and the plurality of teeth are formed.

In aspects, a method of forming the foldable substrate 201 shown in FIG. 2 can comprise machining portions of the substrate to roughly correspond to the shape of the first folding surface area 273. Then, the surface can be treated with various solution to minimize and/or remove surface flaws and/or scratches introduced by the machining.

In aspects, a method of forming the foldable substrate 201 shown in FIG. 2 can comprise locally damaging and/or weaking a network of the glass-based material and/or ceramic based-material (e.g., laser writing and/or sintering, scratching, photolithography) that can be etched with the locally treated (e.g., locally damaging and/or weaking) being preferentially etched to form the predetermined first folding surface area 273.

### EXAMPLES

Various aspects will be further clarified by the following examples. Examples 1-13 and Comparative Examples AA-DD comprise a glass-based substrate (Composition 1 having a nominal composition in mol % of: 63.6 SiO₂; 15.7 Al₂O₃; 10.8 Na₂O; 6.2 Li₂O; 1.16 ZnO; 0.04 SnO₂; and 2.5 P₂O₅) with dimensions of 100 mm by 160 mm in a direction perpendicular to the substrate thickness. The shape of the folded configuration and stress profile of Examples 1-10 and AA-BB were simulated using finite element analysis (FEA), although the shape of the folded configuration can be physically measured (e.g., as the one described in the “Study of Deformation Behavior of Multilayered Sheets Using Digital Image Correlation,” Procedia Manufacturing 47 (2020), 1257-1263). The FEA simulations were performed with the following assumptions: the foldable substrate comprises an elastic modulus of 71 GPa and a Poisson's ratio of 0.22; the adhesive layers comprise a Poisson's ratio of 0.49; the polymer-based portions comprise a Poisson's ratio of 0.49; all interfaces in the foldable apparatus are perfectly bonded with no delamination; a large deformation approach is applicable; and that all components were at 23° C.

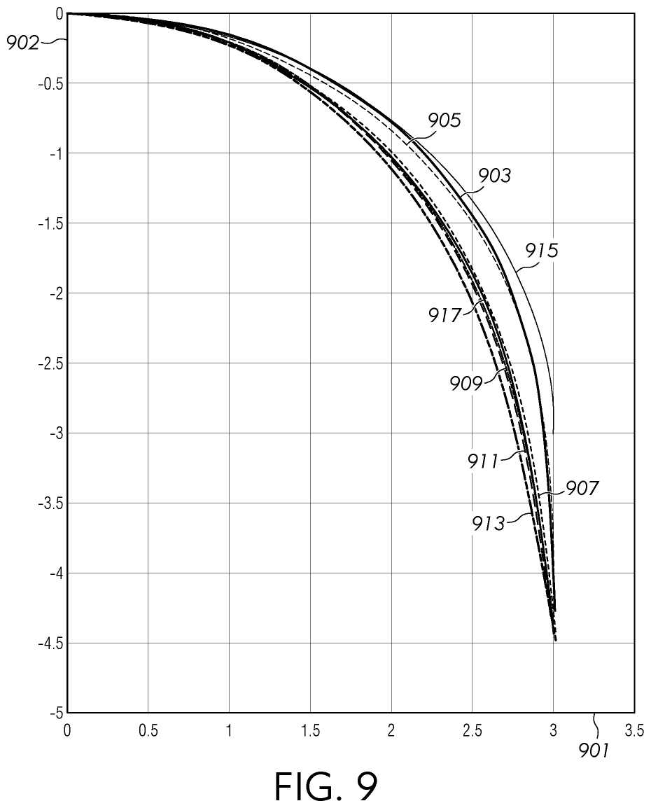

FIG. 9 shows the folded configuration for Examples 1-6 and Comparative Example AA folded to a parallel plate distance of 6 mm in accordance with the Parallel Plate Test. In FIG. 9, the horizontal axis 901 (i.e., x-axis) corresponds to a position in the direction of the parallel plate distance 711 (see FIGS. 7-8), and the vertical axis 902 (i.e., y-axis) corresponds to a position in a direction perpendicular to the direction of the parallel plate distance 711 (see FIGS. 7-8). The origin (i.e., the intersection of 0 on the horizontal axis and 0 on the vertical axis) is defined as the location of the folded configuration at the midline between the parallel plates, which corresponds to the apex of the folded configuration). Comparative Example AA comprised a uniform (e.g., monolithic) substrate thickness of 80 μm without any teeth and without the foldable surface areas described herein. Examples 1-6 comprised a substrate thickness of 150 μm and a central thickness of 80 μm with a plurality of teeth, where a thickness of each tooth was equal to the substrate thickness. Examples 1-3 correspond to the foldable apparatus 403, 405, or 407 shown in FIGS. 4A-4C, respectively, and Examples 4-6 correspond to the foldable apparatus 509, 511, or 513 shown in FIGS. 5A-5C, respectively. Curves 903, 905, 907, 909 911, and 913 in FIG. 9 correspond to Examples 1-6, respectively. Examples 1-6 comprise a maximum tooth width of 100 μm and a maximum distance between adjacent pairs of teeth of 200 μm. Curve 917 corresponds to Comparative Example AA, and curve 915 corresponds to a circle with a radius of 3 mm (corresponding to a diameter and a parallel plate distance of 6 mm). As shown in FIG. 9, curves 913 (Example 6) with an increasing tooth width as the distance from the midline increases has a folded configuration furthest from the circular shape shown in curve 915. Curves 909, 911, and 917 (Examples 4-5 and Comparative Example AA) have about the same folded configuration. Curve 907 (Example 3) with a distance between adjacent pairs of teeth decreasing as the distance from the midline increases is closer to the circular configuration (curve 915) than Example AA (curve 917). Curves 903 and 905 (Examples 1-2) with the tooth width decreasing as the distance from the midline increases have folded configurations closest to the circular profile (curve 915). Consequently, FIG. 9 indicates that for foldable apparatus (e.g., foldable substrates) with a plurality of teeth in the folding region and/or central portion, a more circular folded configuration can be obtained when the tooth width decreases as the distance from the midline increases, as in Examples 1-2.

The maximum value of stress for Examples 1-6 and Comparative Example AA is shown in Table 1. As shown, Comparative Example AA has the lowest value of the maximum fold stress, which is to be expected since there is less material (i.e., volume of the foldable substrate and/or foldable apparatus) being bent. The maximum fold stress of Examples 4-6 is about the same. Example 2 has the largest value of the maximum fold stress, followed by Example 1, and then Example 3. Combining this trend with the discussion of FIG. 9 above, it appears that the maximum fold stress roughly increases as the folded configuration more closely conforms to the circular profile. This is unexpected, as lower values of maximum fold stress would typically be considered desirable; however, as shown in FIG. 9, lower values of maximum fold stress are further from the circular profile. While a greater maximum fold stress is encountered for Examples 1-2 compared to Comparative Example AA (with a thickness corresponding to the central thickness-minimum thickness-of Examples 1-2), as discussed below, the foldable apparatus of FIGS. 2-3 (e.g., Examples 7 and 9) comprises a smaller maximum fold stress than Comparative Example BB (with a thickness corresponding to the average thickness of Examples 7 and 9) for the same parallel plate distance (see FIG. 11) or a smaller parallel plate distance for the same applied force (see Table 2).

TABLE 1
Properties of Examples A-B and AA

| | Foldable | Maximum Fold Stress (MPa) | FIG. 9 |
|---|---|---|---|
| Example | Apparatus | (6 mm parallel plate distance) | curve |
| 1 | 403 (4A) | 2028 | 903 |
| 2 | 405 (4B) | 2117 | 905 |
| 3 | 407 (4C) | 1829 | 907 |
| 4 | 509 (5A) | 1674 | 909 |
| 5 | 511 (5B) | 1661 | 911 |
| 6 | 513 (5C) | 1682 | 913 |
| AA | — | 1250 | 917 |

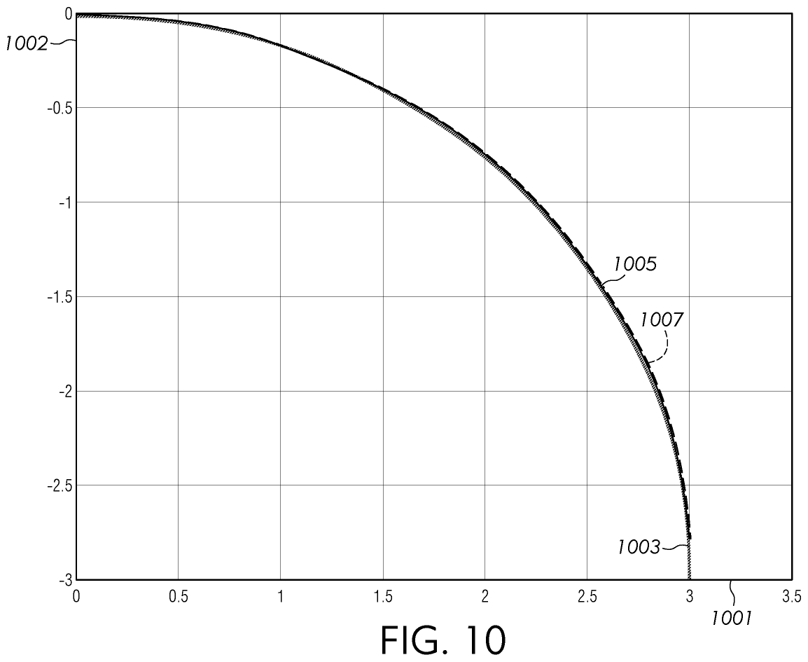

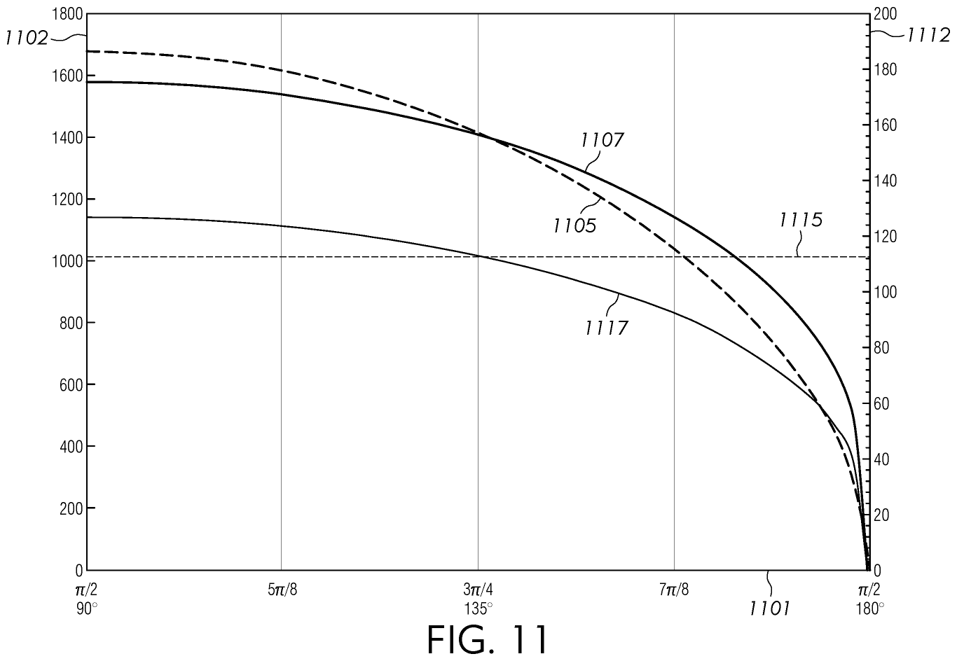

FIG. 10 shows the folded configuration of Examples 7-8. to a parallel plate distance of 6 mm in accordance with the Parallel Plate Test. In FIG. 10, the horizontal axis 1001 (i.e., x-axis) corresponds to a position in the direction of the parallel plate distance 711 (see FIGS. 7-8), and the vertical axis 1002 (i.e., y-axis) corresponds to a position in a direction perpendicular to the direction of the parallel plate distance 711 (see FIGS. 7-8). The origin (i.e., the intersection of 0 on the horizontal axis and 0 on the vertical axis) is defined as the location of the folded configuration at the midline between the parallel plates, which corresponds to the apex of the folded configuration). Examples 7-8 have a substrate thickness of 112.6 μm and a central thickness of 80 μm. Curve 1005 corresponds to Example 7 with the foldable apparatus 101 (e.g., foldable substrate) shown in FIG. 2, and curve 1007 corresponds to Example 8 with the foldable apparatus 301 shown in FIG. 3. Curve 1003 corresponds to a circle with a radius of 3 mm (corresponding to a diameter and a parallel plate distance of 6 mm). As shown in FIG. 10, curves 1005 and 1007 very closely conform to the shape of the circular profile (curve 1003). Consequently, the profiles in FIG. 10 demonstrate that a substantially circular folded configuration can be achieved with the foldable apparatus 101 and 301 shown in FIGS. 2-3. As discussed above, the ability to achieve the circular folded configuration is unexpected since Examples 7-8 has a greater local thickness near the midline than further from the midline in the folding region. Also, this result shown in FIG. 10 is unexpected in light of the folded configurations shown in FIG. 9.

Table 2 presents properties of Examples 9-10 and Comparative Example BB. Examples 9-10 correspond to Examples 7-8, respectively; however, the substrate thickness of 127 μm and a central thickness of 80 μm. Comparative Example BB comprises a uniform (e.g., monolithic) substrate thickness of 112.6 μm, which corresponds to the average thickness of Examples 7 and 9. Examples 9-10 were folded with an applied force of 67.3 Newtons (N). As shown in Table 2, Examples 9-10 achieve an effective radius (of curvature) of 3 mm while Example BB only achieves an effective radius (of curvature) of 6 mm (100% difference). The folded length of Example BB was 13.1 mm, which decreased to 9.42 mm for Examples 9-10 (28% decrease). Example 9 has a maximum fold stress of 1579 MPa, which is less than the maximum fold stress of Example BB. Compared to Example 10, the maximum fold stress is lower for Example 9.

TABLE 2
Properties of Examples 9-10 and Comparative Example B

| | Parallel Plate | | |
|---|---|---|---|
| | Distance (mm) | | |
| | (Effective Bend | Folded | Maximum Fold |
| Example | Radius) (mm) | Length (mm) | Stress (MPa) |
| 9 | 6 (3) | 9.42 | 1579 |
| 10 | 6 (3) | 9.42 | 2411 |
| BB | 6 (3) | 13.1 | 1677 |

FIG. 11 shows the direction (θ) that the foldable substrate is facing along the folded configuration from 90° (π/2) to 180° (π) with the understanding that the trend for 0° to 90° (π/2) is a mirror image of the results shown. The horizontal axis 1101 (i.e., x-axis) shows the direction (θ), the left vertical axis 1102 (i.e., left-hand y-axis) is the magnitude (i.e., absolute value) of the stress on the surface in tension (in MPa), and the right vertical axis 1112 (i.e., right-hand y-axis) is a local thickness (in μm). Curve 1105 corresponds to Comparative Example BB, and curve 1107 corresponds to Example 7 (corresponding to the foldable apparatus 101 shown in FIG. 2). The results in FIG. 11 are measured for the applied force of 67.3 N, as described above with reference to Table 2. As shown in FIG. 11, the magnitude of stress (along vertical axis 1102) is lower for curve 1107 than curve 1105 for angles less than 135° (and from 45° to 135° due to symmetry). Meanwhile, curves 1115 and 1117 use vertical axis 1112 instead of vertical axis 1102. Curve 1115 is a line at the average thickness of Examples 7 and 9 and Comparative Example AA. Curve 1117 shows the thickness profile

$$h ( x ) = \sqrt[3]{\frac{24 {R}^{2} F sin ( \frac{x}{R} + \frac{π}{2} )}{wE}}$$

that was discussed above as the basis for the folded surface areas of foldable apparatus 101 shown in FIG. 2. The thickness for this thickness profile (curve 1117) is greater than the average thickness (curve 1115) from 90° to 135° (or from 45° to 135° due to symmetry). Comparing the sets of curves shown in FIG. 11, the region where the stress in curve 1107 is less than the stress in 1105 (from 90° to 135° or from 45° to 135° due to symmetry) corresponds to the same region where curve 1117 is greater than curve 1115 (i.e., where Example 7 has a greater local thickness than Comparative Example BB). This indicates that the region with greater than average thickness in curves 1107 and 1117 actually corresponds to less stress than if a thinner local thickness was used (see curves 1105 and 1117). As such, the thickness profile for the folding region of the present disclosure can reduce bend-induced stresses relative to a substrate with a uniform thickness in the corresponding folding region, where uniform thickness is equal to the average thickness of the thickness profile of the folding region of the present disclosure. As noted elsewhere, this is unexpected since greater local thickness would be expected to correspond to greater bend-induced stress.

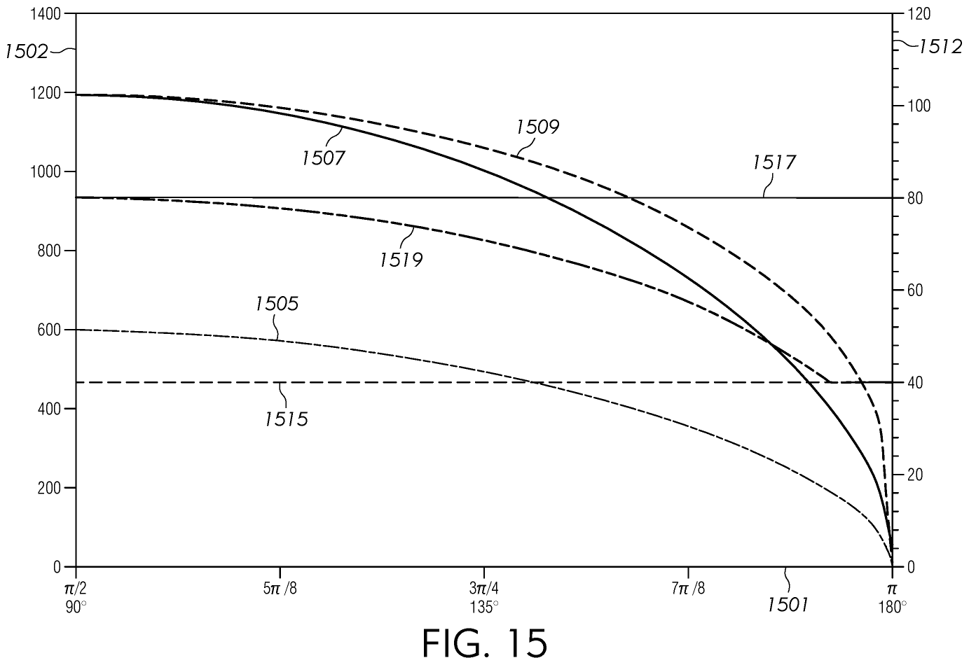

FIGS. 15-17 shows the direction (θ) that the foldable substrate is facing along the folded configuration from 90° (π/2) to 180° (π) with the understanding that the trend for 0° to 90° (π/2) is a mirror image of the results shown. The horizontal axis 1501, 1601, or 1701 (i.e., x-axis) shows the direction (θ), the left vertical axis 1502, 1602, or 1702 (i.e., left-hand y-axis) is the magnitude (i.e., absolute value) of the stress on the surface in tension (in MPa), and the right vertical axis 1512, 1612, or 1712 (i.e., right-hand y-axis) is a local thickness (in μm). In FIGS. 15-17, curve 1507, 1605, or 1705 corresponds to the stress of Comparative Example AA, and curve 1517, 1615, or 1715 shows the corresponding thickness profile of Comparative Example AA that is monolithic (i.e., uniform) with a thickness of 80 μm. Examples 11-13 comprises the thickness profile discussed above with reference to FIG. 2, where the thickness ranges for Examples 11-13 are presented in Table 3.

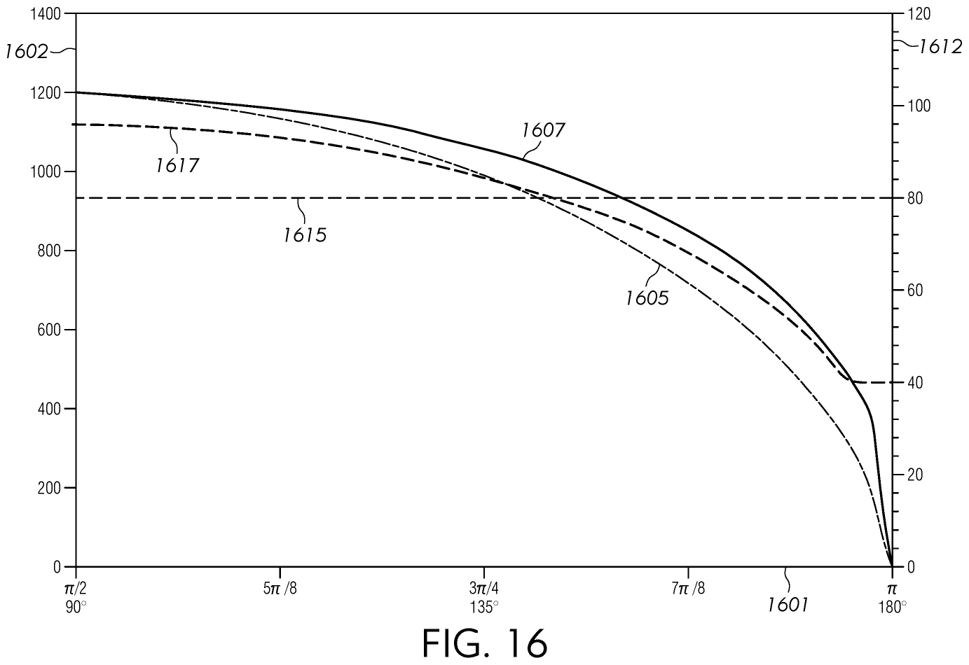

As shown in FIG. 16 and Table 3, Comparative Example AA (curve 1605) exhibits a maximum fold stress of 1191 MPa at a parallel plate distance of 6 mm. In FIG. 16, curve 1607 corresponds to the stress of Example 11, and curve 1617 shows the corresponding thickness profile of Example 11 that increases from 40 μm at the transition region (see 180° or x radians) to 96 μm at the center of the bend (see 90° or π/2 radians) in accordance with the relationship discussed above. As shown in FIG. 16 and Table 3, Example 11 exhibits a maximum fold stress of 1191 MPa at a parallel plate distance of 6 mm. Consequently, Example 11 and Comparative Example AA exhibit the same maximum fold stress (to a parallel plate distance of 6 mm) while Example 11 has a greater thickness (96 μm at the middle of the folding region) than Comparative Example AA (80 μm), which is believed to be the result of the thickness profile that enables Example 11 to achieve a circular bend profile (in contrast to the elliptical bend profile discussed above). The increased thickness at the end of the folding region of Example 11 (relative to Comparative Example AA) which is believed to provide Example 11 with greater puncture resistance than Comparative Example AA.

TABLE 3
Properties of Examples 11-13 and
Comparative Examples AA and CC-DD

| | | Thickness | Maximum | Bend |
|---|---|---|---|---|
| | Parallel Plate | Range | Fold Stress | Force |
| Example | Distance (mm) | (μm) | (MPa) | (N/mm) |
| 11 | 6 | 40 to 96 | 1191 | 0.29 |
| 12 | 5 | 40 to 80 | 1191 | 0.24 |
| 13 | 6 | 80 to 120 | 1492 | 0.57 |
| AA | 6 | 80 | 1191 | 0.24 |
| CC | 6 | 40 | 596 | 0.03 |
| DD | 6 | 120 | 1787 | 0.82 |

In FIG. 15, curve 1505 corresponds to the stress of Comparative Example CC, and curve 1515 shows the corresponding thickness profile of Comparative Example CC that is monolithic (i.e., uniform) with a thickness of 40 μm. As shown in FIG. 15 and Table 3, Comparative Example CC (curve 1505) exhibits a maximum fold stress of 596 MPa at a parallel plate distance of 6 mm. In FIG. 15, curve 1509 corresponds to the stress of Example 12, and curve 1519 shows the corresponding thickness profile of Example 12 that increases from 40 μm at the transition region (see 180° or x radians) to 80 μm at the center of the bend (see 90° or π/2 radians) in accordance with the relationship discussed above. Unlike Example 11 and 13 and Comparative Examples AA and CC-DD, Example 12 was folded to a parallel plate distance of 5 mm instead of 6 mm. As shown in FIG. 15 and Table 3, Example 12 exhibits a maximum fold stress of 1191 MPa at a parallel plate distance of 5 mm. As shown in Table 3, the maximum fold stress at 6 mm for Example 11 and Comparative Example AA at 6 mm is the same as Example 12 at the smaller parallel plate distance of 5 mm. Consequently, Example 12 demonstrates that a thickness profile in accordance with aspects of the present disclosure with a maximum thickness in the folding region (as that of a monolithic thickness with the corresponding maximum thickness) can achieve a smaller parallel plate distance with the same maximum fold stress as that of a comparative substrate with a monolithic thickness equal to the corresponding maximum thickness.

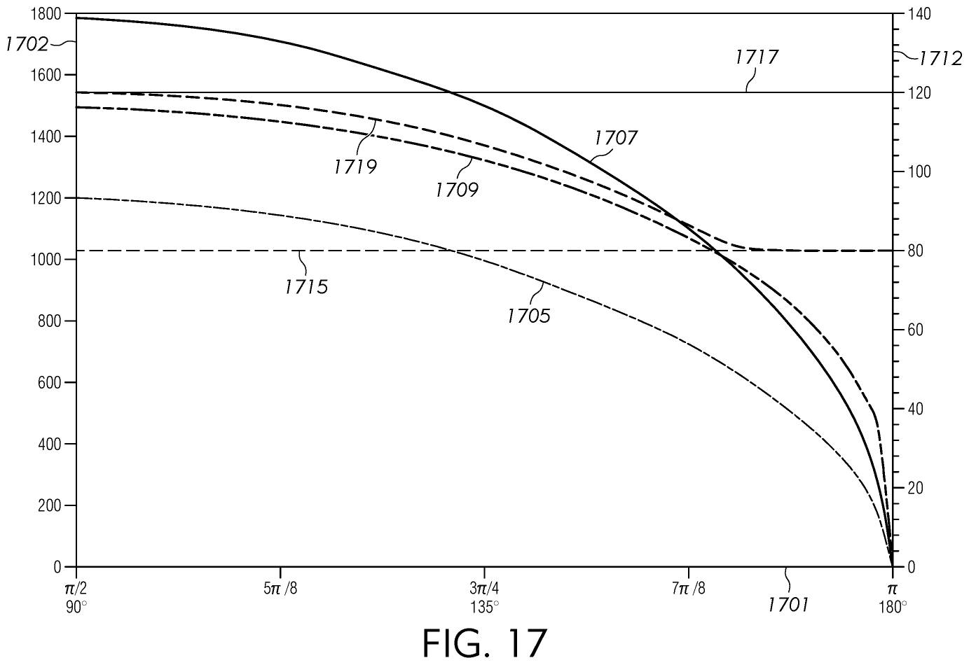

In FIG. 17, curve 1707 corresponds to the stress of Comparative Example DD, and curve 1717 shows the corresponding thickness profile of Comparative Example DD that is monolithic (i.e., uniform) with a thickness of 120 μm. As shown in FIG. 17 and Table 3, Comparative Example DD (curve 1707) exhibits a maximum fold stress of 1782 MPa at a parallel plate distance of 6 mm. In FIG. 17, curve 1709 corresponds to the stress of Example 13, and curve 1719 shows the corresponding thickness profile of Example 13 that increases from 80 μm at the transition region (see 180° or x radians) to 120 μm at the center of the bend (see 90° or π/2 radians) in accordance with the relationship discussed above. Notably, the thickness of Example 13 is greater than that for Examples 11-12. As shown in FIG. 17 and Table 3, Example 13 exhibits a maximum fold stress of 1492 MPa at a parallel plate distance of 6 mm. Consequently, Example 13 and Comparative Example DD have the same maximum thickness in the folding region, but Example 13 exhibits a lower bend stress than Comparative Example DD at the same parallel plate distance of 6 mm, which is believed to be the result of the thickness profile that enables Example 13 to achieve a circular bend profile (in contrast to the elliptical bend profile discussed above).

Table 3 also presented bend forces corresponding to the minimum force to bend the foldable substrate to the achieve the minimum parallel plate distance stated in Table 3. As shown, Example 12 has a bend force of 0.24 N/mm to achieve a parallel plate distance of 5 mm while Example AA has the same bend force to achieve a larger parallel plate distance of 6 mm. Also, comparing Comparative Example DD and Example 13 with the same maximum thickness, the bend force for Example 13 to achieve a parallel plate distance of 6 mm is 0.57 N/mm, which is 30% less than the corresponding bend for Comparative Example DD. This demonstrates that providing the thickness profile in accordance with aspects of the present disclosure provide a reduced bend force to achieve a predetermined parallel plate distance (e.g., 20% or more decrease or 30% or more decrease) than a substrate comprising a uniform thickness equal to the maximum thickness.

The above observations can be combined to provide foldable substrate comprising a low minimum parallel plate distance, high impact resistance, increased durability, reduced fatigue, and reduced incidence of mechanical instabilities. The substrate and/or the portions can comprise glass-based and/or ceramic-based portions, which can provide good dimensional stability, reduced incidence of mechanical instabilities, good impact resistance, and/or good puncture resistance. The portions can comprise glass-based and/or ceramic-based portions comprising one or more compressive stress regions, which can further provide increased impact resistance and/or increased puncture resistance. By providing a substrate comprising a glass-based and/or ceramic-based substrate, the substrate can also provide increased impact resistance and/or puncture resistance while simultaneously facilitating good folding performance. In aspects, the substrate thickness can be sufficiently large (e.g., from about 50 micrometers (microns or μm) to about 2 millimeters) to further enhance impact resistance and puncture resistance. Providing foldable substrates comprising a central portion comprising a central thickness that is less than a substrate thickness (e.g., first thickness of the first portion and/or second thickness of the second portion) (e.g., by about 10 μm or more) can enable a small parallel plate distance (e.g., about 10 millimeters or less, about 5 mm or less, or about 3 mm or less) based on the reduced thickness in the central portion, which can enable the foldability and/or rollability of the foldable substrate and/or foldable apparatus.

The inventors of the present application have determined that the local thickness profile of the folding region described herein can unexpectedly enable the foldable substrate to be folded into a substantially circular folded configuration (e.g., with a folded length of about 1.6 times the corresponding parallel plate distance). This is in contrast to the elliptical folded configuration (e.g., with a folded length of about 2.2 times the corresponding parallel plate distance) for a substrate with a uniform thickness in the region being folded. Additionally, the stress distribution in the folded configuration for a substrate with a uniform thickness is uneven, which can increase an incidence of damage and/or failure of the device relative to the stress distribution for folded foldable substrates with the thickness profile described herein. Unexpectedly, the increasing local thickness profile of the present disclosure enables the circular folded profile that decreases the length of the folded region and decreases stress concentrations along the bend. For example, in aspects, a smoothly varying surface can be provided in the folding region to facilitate folding into the substantially circular folded configuration. Alternatively, in aspects, a plurality of teeth can (e.g., comprising substantially the substrate thickness) can increase a puncture resistance of the folding region while the folding region (excluding the teeth) can comprise the increasing local thickness profile discussed above that can facilitate folding into the substantially circular folded configuration.

In aspects, the foldable apparatus and/or foldable substrates can comprise one or more recesses, for example, a first central surface area recessed from a first major surface by a first distance and/or a second central surface area recessed from a second major surface by a second distance. Providing a first recess opposite a second recess can provide the central thickness that is less than a substrate thickness. Further, providing a first recess opposite a second recess can reduce a maximum bend-induced strain of the foldable apparatus, for example, between a central portion and a first portion and/or second portion since the central portion comprising the central thickness can be closer to a neutral axis of the foldable apparatus and/or foldable substrates than if only a single recess was provided. Additionally, providing the first distance substantially equal to the second distance can reduce the incidence of mechanical instabilities in the central portion, for example, because the foldable substrate is symmetric about a plane comprising a midpoint in the substrate thickness and the central thickness. Moreover, providing a first recess opposite a second recess can reduce a bend-induced strain of a material positioned in the first recess and/or second recess compared to a single recess with a surface recessed by the sum of the first distance and the second distance. Providing a reduced bend-induced strain of a material positioned in the first recess and/or the second recess can enable the use of a wider range of materials because of the reduced strain requirements for the material. For example, stiffer and/or more rigid materials can be positioned in the first recess, which can improve impact resistance, puncture resistance, abrasion resistance, and/or scratch resistance of the foldable apparatus. Additionally, controlling properties of a first material positioned in a first recess and a second material positioned in a second recess can control the position of a neutral axis of the foldable apparatus and/or foldable substrates, which can reduce (e.g., mitigate, eliminate) the incidence of mechanical instabilities, apparatus fatigue, and/or apparatus failure.

In aspects, the foldable apparatus and/or foldable substrates can comprise a first transition region attaching the central portion to the first portion and/or a second transition region attaching the central portion to the second portion. Providing transition regions with smoothly and/or monotonically decreasing (e.g., continuously decreasing) thicknesses can reduce stress concentration in the transition regions and/or avoid optical distortions. Providing a sufficient length of the transition region(s) (e.g., about 0.15 mm or more or about 0.3 mm or more) can avoid optical distortions that may otherwise exist from a sharp change in thickness of the foldable substrate.

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

While various features, elements, or steps of particular aspects may be disclosed using the transitional phrase “comprising,” it is to be understood that alternative aspects, including those that may be described using the transitional phrases “consisting of” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

1. A foldable substrate comprising:
a substrate thickness defined between a first major surface and a second major surface opposite the first major surface:
a first portion comprising the substrate thickness, a first compressive stress region extending to a first depth of compression from the first major surface, a second compressive stress region extending to a second depth of compression from the second major surface:
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a folding region positioned between a first transition region and a second transition region, the first transition region and the second transition region comprising a central thickness less than the substrate thickness, the folding region comprising a first folding surface area and a second folding surface area opposite the first folding surface area, a first folding compressive stress region extending to a first folding depth of compression from the first folding surface area, a second folding compressive stress region extending to a second folding depth of compression from the second folding surface area, a folding width of the folding region is defined between the first transition region and the second transition region, and a local thickness of the folding region between the first folding surface area and the second folding surface area in a direction of the substrate thickness increases as a distance from a midline of the folding region decreases,
wherein the foldable substrate comprises a glass-based material or a ceramic-based material.

2. The foldable substrate of claim 1, wherein the local thickness of the folding region varies between the central thickness and the substrate thickness with the local thickness at the midline of the folding region substantially equal to the substrate thickness.

3. The foldable substrate of claim 1, wherein the local thickness of the folding region as a function of the position along the folding width of the folding region is proportional to a cube root of a sine of a fractional position, the fractional position scaled to range from 0 to pi radians across the folding width of the folding region.

4. The foldable substrate of claim 1, wherein a thickness of the first transition region smoothly decreases from the substrate thickness to the central thickness as a distance from the first portion increases.

5. A foldable substrate comprising:
a substrate thickness defined between a first major surface and a second major surface opposite the first major surface:
a first portion comprising the substrate thickness, a first compressive stress region extending to a first depth of compression from the first major surface, a second compressive stress region extending to a second depth of compression from the second major surface:
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a folding region positioned between a first transition region and a second transition region, the first transition region and the second transition region comprising a central thickness less than the substrate thickness, the folding region comprising a plurality of teeth extending from a first folding surface area, the first folding surface area opposite a second folding surface, a folding width of the folding region is defined between the first transition region and the second transition region, and a local thickness of the folding region between the first folding surface area and a second folding surface area excluding the plurality of teeth increases as a distance from a midline of the folding region decreases,
wherein the foldable substrate comprises a glass-based material or a ceramic-based material.

6. The foldable substrate of claim 5, wherein a tooth thickness of a tooth of the plurality of teeth is substantially equal to the substrate thickness.

7. The foldable substrate of claim 5, wherein the midline of the folding region does not comprise a tooth of the plurality of teeth.

8. The foldable substrate of claim 5, wherein a first width of a first tooth of the plurality of teeth is greater than a second width of a second tooth of the plurality of teeth, the first tooth is closer to the midline of the folding region than the second tooth is to the midline.

9. The foldable substrate of claim 5, wherein a first width of a first tooth of the plurality of teeth is less than a second width of a second tooth of the plurality of teeth, the first tooth is closer to the midline of the folding region than the second tooth is to the midline.

10. The foldable substrate of claim 5, wherein a first distance between a first adjacent pair of teeth of the plurality of teeth is less than a second distance between a second adjacent pair of teeth of the plurality of teeth, the first adjacent pair of teeth is closer to the midline of the folding region than the second adjacent pair of teeth is to the midline.

11. The foldable substrate of claim 5, wherein a first distance between a first adjacent pair of teeth of the plurality of teeth is less than a second distance between a second adjacent pair of teeth of the plurality of teeth, the first adjacent pair of teeth is closer to the midline of the folding region than the second adjacent pair of teeth is to the midline.

12. The foldable substrate of claim 5, wherein the local thickness of the folding region as a function of the position along the folding width of the folding region is proportional to a cube root of a sine of a fractional position, the fractional position scaled to range from 0 to pi radians across the folding width of the folding region.

13. The foldable substrate of claim 5, wherein a thickness of the first transition region excluding the plurality of teeth smoothly decreases from the substrate thickness to the central thickness as a distance from the first portion increases.

14. The foldable substrate of claim 5, wherein the folding region is symmetric about a plane extending through the midline of the folding region and equidistant from the first portion and the second portion.

15. The foldable substrate of claim 5, wherein a folded configuration of the foldable substrate folded about the midline of the folding region in a Parallel Plate Test is substantially circular, and wherein the folding width of the folding region is substantially equal to a minimum parallel plate distance of the foldable substrate in a Parallel Plate Test.

16. The foldable substrate of claim 5, wherein the foldable substrate achieves a parallel plate distance of 3 millimeters.

17. The foldable substrate of claim 5, wherein the first compressive stress region comprises a first maximum compressive stress of about 400 MegaPascals or more, the second compressive stress region comprises a second maximum compressive stress, the third compressive stress region comprises a third maximum compressive stress of about 400 MegaPascals or more, and the fourth compressive stress region comprises a fourth maximum compressive stress, wherein the second maximum compressive stress is about 400 MegaPascals or more, and the fourth maximum compressive stress is about 400 MegaPascals or more.

18. The foldable substrate of claim 5, wherein the substrate thickness is in a range from about 50 micrometers to about 2 millimeters, preferably in a range from about 100 micrometers to about 200 micrometers.

19. The foldable substrate of claim 5, wherein the central thickness in a range from about 25 micrometers to about 120 micrometers, preferably in a range from about 25 micrometers to about 60 micrometers.

20. A consumer electronic product, comprising:
a housing comprising a front surface, a back surface, and side surfaces:
electrical components at least partially within the housing, the electrical components comprising a controller, a memory, and a display, the display at or adjacent the front surface of the housing; and
a cover substrate disposed over the display,
wherein at least one of a portion of the housing or the cover substrate comprises the foldable substrate of claim 5.
